(19) United States
(12) Patent Application Publication
(10) Pub. No.: US 2025/0098288 A1
(43) Pub. Date: Mar. 20, 2025

(54) BACKSIDE RESISTOR CONNECTED TO BACKSIDE BACK END OF LINE NETWORK

(71) Applicant: INTERNATIONAL BUSINESS MACHINES CORPORATION, ARMONK, NY (US)

(72) Inventors: JENS HAETTY, Halfmoon, NY (US); Christopher Murphy, Red Hook, NY (US); Lawrence A. Clevenger, Saratoga Springs, NY (US); Brent A. Anderson, Jericho, VT (US); Ruilong Xie, Niskayuna, NY (US)

(21) Appl. No.: 18/470,646

(22) Filed: Sep. 20, 2023

(51) Int. Cl. H01L 27/06; H01L 23/522

(52) U.S. Cl. CPC H10D 84/811; H01L 23/5226; H01L 23/5228; H10D 1/474

(57) ABSTRACT

A semiconductor integrated circuit (IC) device includes a backside resistor and a back end of the line (BEOL) network. The backside resistor is located upon a backside of the semiconductor IC device and may be vertically located between a front end of line (FEOL) microdevice, such as a diode and/or a transistor, and the BEOL network. The backside resistor is connected to the backside BEOL network and may be utilized to route current between different conductive pathways within the backside BEOL network or between the backside BEOL network and a frontside BEOL network.

### BACKGROUND

Various embodiments of the present disclosure generally relate to semiconductor integrated circuit (IC) device fabrication operations and resulting semiconductor IC devices. More specifically the various embodiments of the present disclosure relate to a backside resistor that is connected to at least a backside back end of line (BEOL) network.

A backside BEOL network is a second BEOL network on an opposing device side relative to a frontside BEOL network within a semiconductor IC device. Backside BEOL networks may enable future semiconductor IC device scaling and may ease wiring routing complexities within the semiconductor IC device.

### SUMMARY

In an embodiment of the present disclosure, a semiconductor integrated circuit (IC) device is presented. The semiconductor IC device includes a frontside back end of line (BEOL) network, a deep via contact that is directly connected to a backside resistor and that is directly connected to the frontside BEOL network, and a backside BEOL network that includes a conductive pathway directly connected to the backside resistor. By associating the backside resistor with the backside BEOL network, the presented semiconductor IC device may be further scaled (i.e., shrunk is size) and/or may have reduced signal and/or power wiring routing complexities therein. Further, by placing the backside resistor between the deep via contact and the backside BEOL network, the backside resistor may be located relatively closer to front end of line (FEOL) microdevices which may provide for increased semiconductor IC performance (e.g., associated lower latencies, or the like). Further, by placing the backside resistor between the deep via contact and the backside BEOL network, the semiconductor IC device may have relatively improved area utilization and relatively increased thermal dissipation (e.g., due to reduced self-heating, or the like).

In an example, the backside resistor can be vertically between (i.e., between in one or more vertical planes) the deep via contact and the backside BEOL network. By locating the backside resistor vertically between the deep via contact and the backside BEOL network, the backside resistor may be located relatively closer to the FEOL microdevice(s) which may provide for relatively increased semiconductor IC performance, relatively improved area utilization, and relatively increased thermal dissipation.

In examples, a top surface of the backside resistor can be directly connected to a bottom surface of the deep via contact or a bottom surface of the backside resistor can be connected to backside BEOL network. By structurally associating the backside resistor and the deep via contact with the backside BEOL network, the presented semiconductor IC device may be further scaled and/or may have reduced signal and/or power wiring routing complexities therein.

In an example, the backside resistor can be composed of a first conductor and the deep via contact can be composed of a second conductor that is different than the first conductor. The material and/or geometry of the backside resistor may be chosen to achieve a predetermined resistance of the backside resistor which may result in the backside resistor being composed of a different material or metal relative to the other conductive materials within the semiconductor IC device.

In an example, the deep via contact and the backside resistor can route current between the frontside BEOL network and the backside BEOL network. As such, the deep via contact and the backside resistor may be a conduit for current flow between the backside and frontside of the semiconductor IC device which may reduce reduced signal and/or power wiring routing complexities therein.

In an example, deep via contact and the backside resistor can provide a substantially same electrical potential to both the frontside BEOL network and to the backside BEOL network. As such, the deep via contact and the backside resistor may be a voltage node for electrical potential to both the backside BEOL network and the frontside BEOL network, which may reduce reduced signal and/or power wiring routing complexities therebetween.

In an example, a top surface of the backside resistor can be coplanar with a bottom surface of a backside contact associated with a front end of line (FEOL) microdevice. As such, the backside resistor may be located relatively closer to the FEOL microdevice, which may provide for relatively increased semiconductor IC performance, relatively improved area utilization, and relatively increased thermal dissipation.

In an example, a bottom surface of the backside resistor can be below a bottom surface of a backside contact associated with a front end of line (FEOL) microdevice. As such, the backside resistor may be located relatively closer to the FEOL microdevice, which may provide for relatively increased semiconductor IC performance, relatively improved area utilization, and relatively increased thermal dissipation.

In an example, the backside resistor can be below a shallow trench isolation (STI) region. As STI region(s) separate FEOL microdevices, the backside resistor may be located underneath such STI region that separates FEOL microdevices, which may provide for relatively improved area utilization between the FEOL microdevices.

In an example, the backside resistor can be horizontally between (e.g., between elements located upon separated vertical planes, or the like) a first front end of line (FEOL) diode and a second FEOL diode. Therefore, the backside resistor may be between FEOL diodes, which may provide for relatively improved area utilization there between.

In an embodiment of the present disclosure, a semiconductor integrated circuit (IC) device is presented. The semiconductor IC device includes a backside resistor and a backside BEOL network. The backside BEOL network includes a first conductive pathway directly connected to the backside resistor and a second conductive pathway directly connected to the backside resistor. By associating the backside resistor with the backside BEOL network, the presented semiconductor IC device may be further scaled (i.e., shrunk is size) and/or may have reduced signal and/or power wiring routing complexities therein. Further, the backside resistor may be located relatively closer to a front end of line (FEOL) microdevice(s) which may provide for increase semiconductor IC performance (e.g., associated lower latencies, or the like). Further, the backside resistor may be located between the FEOL microdevice(s) and the backside BEOL network, which may result in relatively improved area utilization and relatively increased thermal dissipation (e.g., due to reduced self-heating, or the like).

In an example, the backside resistor can be vertically between a front end of line (FEOL) shallow trench isolation (STI) region and the backside BEOL network. By locating the backside resistor vertically between the FEOL STI region and the backside BEOL network, the backside resistor may be located relatively closer to one or more FEOL microdevice(s) associated with the FEOL STI region which may provide for relatively increased semiconductor IC performance, relatively improved area utilization, and relatively increased thermal dissipation.

In examples, a bottom surface of the backside resistor can be directly connected to the first conductive pathway or a bottom surface of the backside resistor can be directly connected to the second conductive pathway. By structurally associating the backside resistor and the deep via contact with the backside BEOL network, the presented semiconductor IC device may be further scaled and/or may have reduced signal and/or power wiring routing complexities therein.

In an example, the backside resistor can be composed of a first conductor and both the first conductive pathway and the second conductive pathway can be composed of a second conductor that is different than the first conductor. The material and/or geometry of the backside resistor may be chosen to achieve a predetermined resistance of the backside resistor which may result in the backside resistor being composed of a different material or metal relative to the other conductive materials within the semiconductor IC device.

In an example, the backside resistor can route current between the first conductive pathway and the second conductive pathway within the backside BEOL network. As such, the backside resistor may be a conduit for current flow within the backside BEOL network, which may reduce reduced signal and/or power wiring routing complexities within the semiconductor IC device.

In an example, a top surface of the backside resistor can be coplanar with a bottom surface of a backside contact associated with a front end of line (FEOL) microdevice. As such, the backside resistor may be located relatively closer to the FEOL microdevice, which may provide for relatively increased semiconductor IC performance, relatively improved area utilization, and relatively increased thermal dissipation.

In an example, the backside resistor can be horizontally between a first front end of line (FEOL) diode and a second FEOL diode. Therefore, the backside resistor may be between FEOL diodes, which may provide for relatively improved area utilization there between.

In another embodiment of the present disclosure, a semiconductor integrated circuit (IC) device method is presented. The method includes forming a backside resistor upon a backside of a front end of line (FEOL) shallow trench isolation (STI) region and upon a bottom surface of a deep via contact. The method further includes forming a backside capping layer upon and around the backside resistor and upon the FEOL STI region. The method further includes forming a backside back end of line (BEOL) network upon the backside capping layer. The backside BEOL network includes a conductive pathway directly connected to the backside resistor. By associating the backside resistor with the backside BEOL network, the presented semiconductor IC device may be further scaled (i.e., shrunk is size) and/or may have reduced signal and/or power wiring routing complexities therein. Further, by placing the backside resistor between the deep via contact and the backside BEOL network, the backside resistor may be located relatively closer to front end of line (FEOL) microdevices which may provide for increase semiconductor IC performance (e.g., associated lower latencies, or the like). Further, by placing the backside resistor between the deep via contact and the backside BEOL network, the semiconductor IC device may have relatively improved area utilization and relatively increased thermal dissipation (e.g., due to reduced self-heating, or the like).

These and other embodiments, features, aspects, and advantages will become better understood with reference to the following description, appended claims, and accompanying drawings.

### BRIEF DESCRIPTION OF THE DRAWINGS

FIG. 1 depicts a semiconductor IC device that includes a backside resistor that is connected to a backside BEOL network, in accordance with one or more embodiments of the disclosure.

FIG. 2 through FIG. 18 depict fabrication views of a semiconductor IC device that includes a backside resistor that is connected to a backside BEOL network, in accordance with one or more embodiments of the disclosure.

FIG. 19 depicts a flow diagram illustrating a semiconductor IC device fabrication method to fabricate a semiconductor IC device that includes a backside resistor that is connected to a backside BEOL network, in accordance with one or more embodiments of the disclosure.

FIG. 20 depicts a semiconductor IC device that includes a backside resistor that is connected to a backside BEOL network, in accordance with one or more embodiments of the disclosure.

### DETAILED DESCRIPTION

Embodiments of the disclosure recognize that integrating a backside resistor with a backside BEOL network is desirable. As such, the embodiments of the present disclosure provide a fabrication scheme to fabricate a semiconductor IC device that includes a backside resistor that is connected to a backside BEOL network. The backside resistor geometry and/or material may be chosen to achieve a predetermined resistance across the backside resistor for beneficial or otherwise predetermined semiconductor IC device operations. The utilization of backside BEOL network may reduce the footprint area of the applicable circuit relative to other resistor placement schemes. Further, the backside resistor may utilize the same or similar fabrication stages to fabricate other semiconductor IC device structures, which may decrease fabrication complexities of the semiconductor IC device.

Although this detailed description includes examples of how embodiments of the disclosure can be implemented to form an exemplary semiconductor IC device with GAA FETs and/or diodes, implementation of the teachings recited herein are not necessarily limited to a particular type of microdevice type, FET structure or combination of materials depicted or described. Rather, embodiments of the present disclosure are capable of being implemented in conjunction with other microdevice types or materials, now known or later developed, wherein it is desirable for the semiconductor IC device to include a backside resistor that is connected to a backside BEOL network.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor IC devices are well known and so, in the interest of brevity, many conventional steps will only be mentioned briefly herein or will be omitted entirely without providing the well-known process details.

In general, the various processes used to form a semiconductor IC device that will be packaged into a final or packaged IC, fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion, by ion implantation, or otherwise incorporating applicable impurities. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to a description of technologies that are more specifically relevant to the present disclosure, transistors and diodes are types of microdevices commonly found in a wide variety of semiconductor IC devices. Typical semiconductor IC devices may be formed using active regions of a wafer. The active regions are defined by isolation regions used to separate and electrically isolate adjacent semiconductor IC devices. For example, in an IC having a plurality of GAA FETs, each GAA FET has a source and a drain that are formed in an active region of a semiconductor layer by implanting or otherwise incorporating n-type or p-type impurities in the respective source and the drain material. Disposed between the source and the drain is a channel (or body) region. Disposed around the channel is the gate. The gate and the channel are spaced apart by a dielectric layer.

GAA FETs may be fabricated using so-called complementary metal oxide semiconductor (CMOS) fabrication technologies. In general, CMOS is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode.

The wafer footprint of a GAA FET is related to the electrical conductivity of the channel material. If the channel material has a relatively high conductivity, the GAA FET can be made with a correspondingly smaller wafer footprint. A known method of increasing channel conductivity and decreasing GAA FET size is to form the channel as a nanostructure, such as a nanowire or nanosheet. These GAA FETs provide a relatively small FET footprint by forming the channel as a series of vertical nanostructures.

In a known GAA configuration, a nanostructure-based FET includes a source region, a drain region, and stacked nanostructure channels between the source and drain regions. A gate surrounds the stacked nanostructure channels and regulates electron and hole flow through the nanostructure channels between the source and drain regions. GAA FETs may be fabricated by forming alternating layers of channel nanostructure and sacrificial nanostructure layers. The sacrificial nanostructure layers are released from the channel nanostructures before the GAA FET device is finalized. For n-type GAA FETs, the channel nanostructure layers may be silicon (Si) and the sacrificial nanostructure layers may be silicon germanium (SiGe). For p-type GAA FETs, in some implementations, the channel nanostructure layers may be SiGe and the sacrificial nanostructure layers may be Si. In other implementations, p-type GAA FETs, the channel nanostructure may be Si, and the sacrificial nanostructure can be SiGe. In some implementations, the channel nanostructure layers may initially be Si and can be converted to SiGe or other material, after sacrificial nanostructure layers are removed.

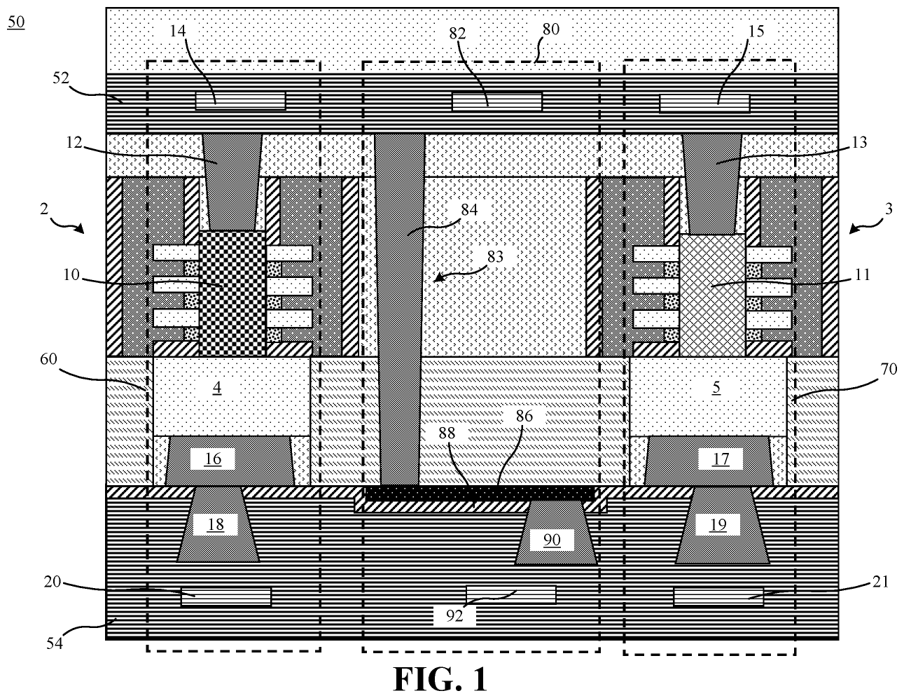

Turning now to a more detailed description an embodiment of the disclosure, FIG. 1 depicts a semiconductor IC device 50 that includes a backside resistor 86 that is connected to a backside BEOL network 54, in accordance with one or more embodiments of the disclosure. The semiconductor IC device 50 includes a resistor region 80, which includes the backside resistor 86, and may further include a diode region 60 and/or a diode region 70.

The diode region 60 includes a diode 2 and the diode region 70 includes a diode 3. An anode 10 of diode 2 is electrically connected to a conductive pathway 14 within a frontside BEOL network 52 and a cathode 16, which may also be referred to herein as a backside contact, of diode 2 is electrically connected to a conductive pathway 20 within the backside BEOL network 54. Similarly, a cathode 11 of diode 3 is electrically connected to a conductive pathway 15 within the frontside BEOL network 52 and an anode 17 of diode 3 is electrically connected to a conductive pathway 21 within the backside BEOL network 54.

Anode 10 may be a P+ doped (i.e., heavily P doped) region and may be directly connected to an intrinsic substrate region 4 and may be connected to a frontside contact 12. Intrinsic substrate region 4 may be directly connected to a backside contact 16. Frontside contact 12 may be electrically connected to the conductive pathway 14 within the front side BEOL network 52. Similarly, backside contact 16 may be electrically connected to the conductive pathway 20 within the backside BEOL network 54 (e.g., by way of backside via 18, or the like). The conductive pathway 14 may carry a positive potential, such as VDD, and the conductive pathway 20 may carry a negative or ground potential, such as VSS.

Cathode 11 may be a N+ doped (i.e., heavily N doped) region and may be directly connected to an intrinsic substrate region 5 and may be connected to a frontside contact 13. Intrinsic substrate region 5 may be directly connected to a backside contact 17. Frontside contact 13 may be electrically connected to the conductive pathway 15 within the front side BEOL network 52. Similarly, backside contact 17 may be electrically connected to the conductive pathway 21 within the backside BEOL network 54 (e.g., by way of backside via 19, or the like). The conductive pathway 15 may carry a negative or ground potential, such as VSS, and the conductive pathway 21 may carry a positive potential, such as VDD.

In the depicted arrangement, the anode and cathode regions of the diodes 2, 3, may be formed above and below a substrate which allows for a relatively thinner substrate to be utilized and may assist in reducing a thickness of the semiconductor IC device 50.

The resistor region 80 includes a conductive structure 83 that is directly connected to backside resistor 86. The conductive structure 83 may be a deep via contact 84, as depicted, or other through conductor structure or through semiconductor structure, such as a heavily doped region. The backside resistor 86 is located vertically between (e.g., between elements located upon separated horizontal planes, or the like) the diodes 2, 3 and the backside BEOL network 54 and is electrically connected to a conductive pathway 92 within the backside BEOL network 54 (e.g., by way of backside via 90, or the like). In a particular example, a bottom surface of the conductive structure 83 is directly connected to the top surface of the backside resistor 86 and a bottom surface of the backside resistor 86 is electrically connected to the conductive pathway 92.

The combination of the conductive structure 83 and the backside resistor 86 may route current between the frontside BEOL network 52 and the backside BEOL network 54 for microdevice (diode 2, diode 3, GAA FET, or the like) operations. For instance, conductive pathway 82 and conductive pathway 14 may be electrically connected, conductive pathway 82 and conductive pathway 15 may be electrically connected, conductive pathway 92 and conductive pathway 20 may be electrically connected, or conductive pathway 92 and conductive pathway 21 may be electrically connected.

In the depicted example, a backside capping layer 88 may be located upon a backside of the resistor 86 and may be vertically located between backside contacts 18, 19 and the backside BEOL network 54.

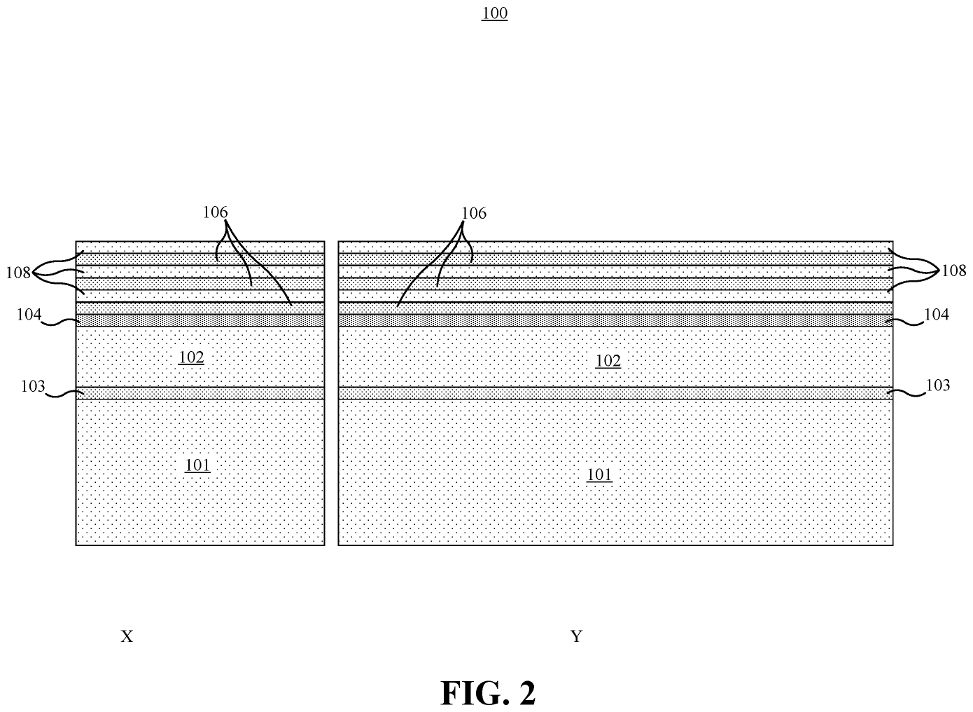

Turning now to a more detailed description of fabrication operations and resulting structures according to embodiments of the disclosure, FIGS. 2-18 depict a semiconductor IC device 100 device that includes, or is to include, a backside resistor that is connected to a backside BEOL network after various fabrication operations. For ease of illustration, the fabrication operations depicted therein will be described in the context of forming elements of GAA FETs in a logic region, depicted in an X cross-section view, of the semiconductor IC device 100, in possible conjunction with forming elements of diode(s) within respective diode regions and elements associated with the backside resistor within a resistor region, depicted in a Y cross-section view, of the semiconductor IC device 100.

Although the cross-sectional structural diagrams depicted in the drawings are two-dimensional, it is understood that the diagrams depicted represent three-dimensional devices. For clarity, the term “same region type” or the like is defined herein to be regions of the semiconductor IC device that share the same type of semiconductor dopants or impurities and/or charges and need not be in the same physical location.

FIG. 2 depicts cross-sectional views of the semiconductor IC device 100 after initial fabrication operations, in accordance with embodiments of the present disclosure. In the present fabrication stage, one or more nanolayers are formed upon a substrate.

The substrate may include a multilayered substrate that includes an upper substrate 102 and a lower substrate 101. An etch stop layer 103 may be located between the upper substrate 102 and the lower substrate 101. The etch stop layer 103 is generally formed of a material with etch selectivity to upper substrate 102 and/or lower substrate 101. As used herein, the terms “selective”, “selectively”, “selectivity”, or the like, in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

Non-limiting examples of suitable materials for the upper substrate 102 and/or lower substrate 101 include Si (silicon), strained Si, SiC (silicon carbide), Ge (germanium), SiGe (silicon germanium), SiGe:C (silicon-germanium-carbon), Si alloys, Ge alloys, III-V materials (e.g., GaAs (gallium arsenide), InAs (indium arsenide), InP (indium phosphide), or aluminum arsenide (AlAs)), II-VI materials (e.g., CdSe (cadmium selenide), CdS (cadmium sulfide), CdTe (cadmium telluride), ZnO (zinc oxide), ZnSe (zinc selenide), ZnS (zinc sulfide), or ZnTe (zinc telluride)), or any combination thereof. Other non-limiting examples of semiconductor materials include III-V materials, for example, indium phosphide (InP), gallium arsenide (GaAs), aluminum arsenide (AlAs), or any combination thereof. The III-V materials can include at least one “III element,” such as aluminum (Al), boron (B), gallium (Ga), indium (In), and at least one “V element,” such as nitrogen (N), phosphorous (P), arsenic (As), antimony (Sb).

Nanolayers may be formed by initially fabricating a sacrificial nanolayer 104 upon substrate 102. Further nanolayers may be formed by fabricating an alternating series of sacrificial nanolayers 106, such as SiGe sacrificial nanolayers, and active nanolayers 108, such as Si nanolayers, upon the sacrificial nanolayer 104. The sacrificial nanolayers 106 can have Ge % ranging from 20% to 45%. In an implementation, the sacrificial nanolayer 104 may be epitaxially grown from the substrate 102 and the alternating active sacrificial nanolayer 106 and active nanolayer 108 may be formed by epitaxially growing one layer and then the next until the desired number and desired thicknesses of the layers are achieved. Any number of alternating nanolayers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

In some embodiments of the disclosure, the active nanolayers 108 are formed from Si and can include, for example, monocrystalline Si. The active nanolayers 108 can have a thickness from, for example, 4 to 12 nm. In embodiments the sacrificial nanolayers 106 are formed from SiGe and the sacrificial nanolayers 106 can have a thickness of, for example, from 4 to 12 nm. The sacrificial nanolayers 106 can have Ge % ranging from 20% to 45%. The sacrificial nanolayer 104 may be formed by epitaxially growing a SiGe layer with high Ge %, ranging from 50% to 70%. In some embodiments, the sacrificial nanolayer 104 is formed of a material that is sufficiently different from the sacrificial nanolayers 106 and active nanolayers 108, such that the sacrificial nanolayer 104 can be selectively etched with minimal removal of the sacrificial nanolayers 106 and active nanolayers 108, and/or vice versa. The sacrificial nanolayer 104 can have a thickness of, for example, from 4 to 15 nm.

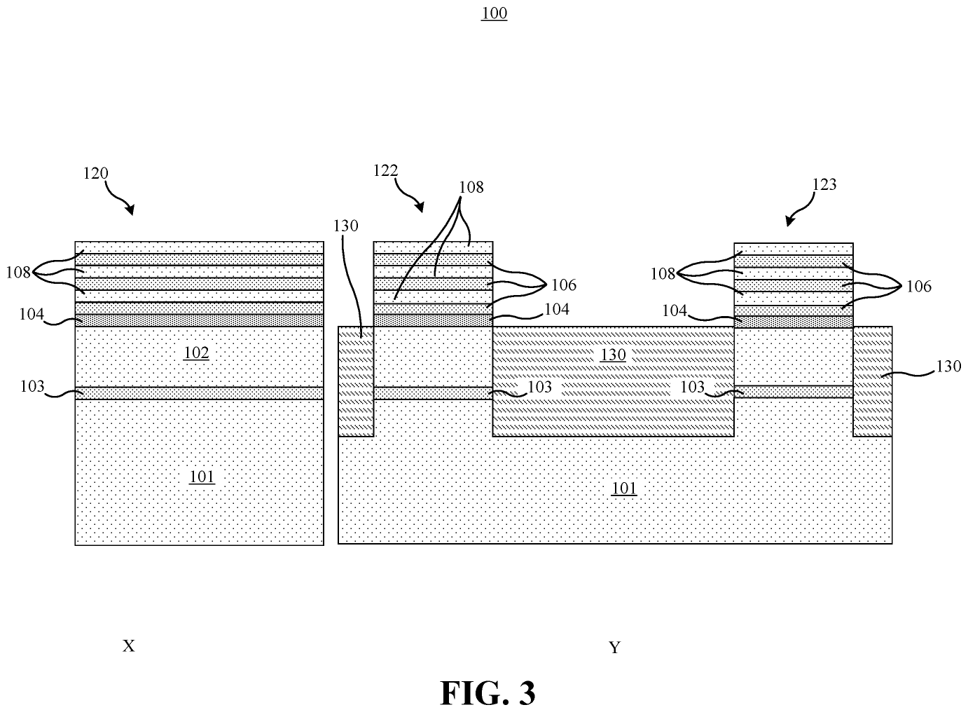

FIG. 3 depicts cross-sectional views of semiconductor IC device 100 shown after exemplary fabrication operation(s), in accordance with one or more embodiments. In the depicted fabrication stage, one or more nanolayer stack(s) 120 are patterned in the logic region and a nanosheet stack 122 and a nanosheet stack 123 are formed in the diode regions. Further in the present fabrication stage, shallow trench isolation (STI) region(s) 130 may be formed within the upper substrate 102 next to nanolayer stacks 120, 122, and/or 123.

A mask layer (not shown) that may be used to pattern the nanolayers into nanolayer stacks 120, 122, and/or 123 may be initially formed upon the top nanolayer. The mask layer may be patterned by photolithography which resultantly exposes portions of the underlying top nanolayer while protecting other portions of the underlying nanolayers.

The nanolayer stacks 120, 122, and/or 123 may be patterned by removing respective undesired portion(s) or section(s) of the sacrificial nanolayer 104, sacrificial nanolayers 106, and active nanolayers 108 while retaining respective desired portions thereof. The removal of undesired portions of the sacrificial nanolayer 104, sacrificial nanolayers 106, and active nanolayers 108 can be accomplished using, for example, lithography and etch processes. The removal of such undesired portions may further remove undesired portions of upper substrate 102 down to the etch stop layer 103 that are adjacent to respective footprints of nanolayer stacks 120, 122, and/or 123. The desired portions of the sacrificial nanolayer 104, sacrificial nanolayers 106, and active nanolayers 108 may be protected by the patterned mask layer and resultingly form the nanolayer stacks 120, 122, and/or 123.

Further in the present fabrication stage, STI region(s) 130 may be formed upon and/or within the recessed upper substrate 102 adjacent to respective footprints of nanolayer stacks 120, 122, and/or 123. For example, STI region(s) 130 may be formed within the recessed upper substrate 102 adjacent to the nanolayer stacks 120 (into and/or out of the page), STI region(s) 130 may be formed within the recessed upper substrate 102 adjacent to the nanolayer stacks 122, 123. In the embodiment depicted, a top surface of one or more STI region(s) 130 may be coplanar with a top surface of upper substrate 102. STI region(s) 130 may be formed by depositing STI liner upon the etch stop layer 103 and upon the upper substrate adjacent to the footprint of nanolayer stacks 120, 122, and/or 123. Subsequently, STI region(s) 130 may be further formed by depositing STI dielectric material upon the STI liner. An etch back, recess, or the like, may occur to remove undesired or over formed STI liner and/or STI dielectric material. The STI region(s) 130 may electrically isolate or at least partially electrically separate components or features of neighboring microdevices, or the like.

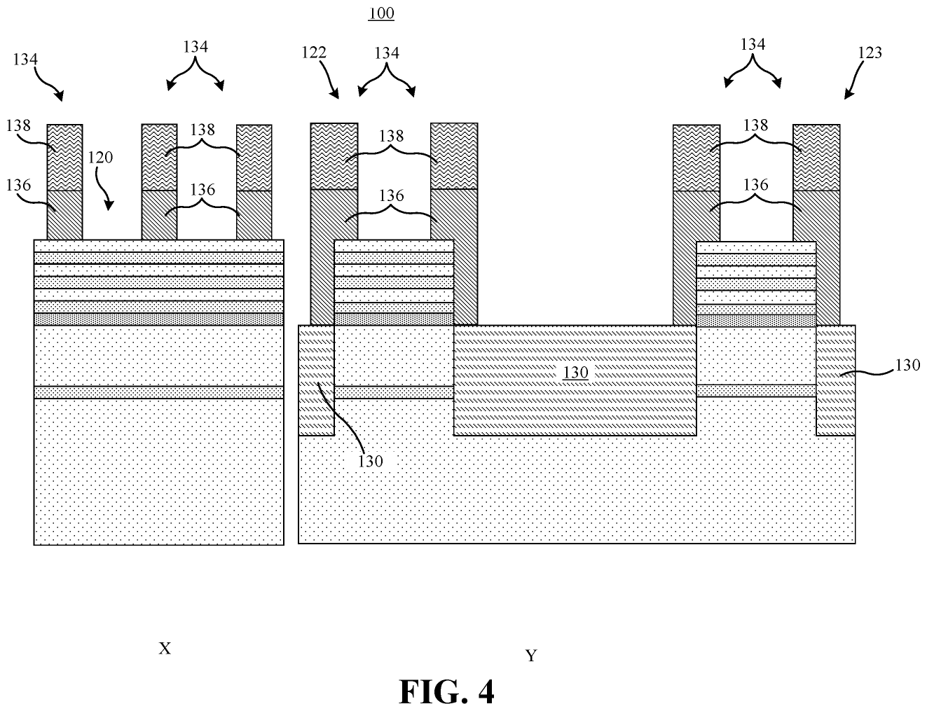

FIG. 4 depicts cross-sectional views of semiconductor IC device 100 shown after exemplary fabrication operation(s), in accordance with one or more embodiments. In the depicted fabrication stage, one or more sacrificial gate structures 134 are formed upon the STI region(s) 130 and upon and around the nanolayer stacks 120, 122, and/or 123. Sacrificial gate structure(s) 134 may include a sacrificial gate liner (not shown), a sacrificial gate 136, and a sacrificial gate cap 138.

The sacrificial gate structure(s) 134 may be formed by depositing a sacrificial gate liner layer (e.g., a dielectric, oxide, or the like) upon STI regions and upon and around nanolayer stacks 120, 122, and/or 123. The sacrificial gate structure 134 may further be formed by subsequently depositing a sacrificial gate layer (e.g., amorphous silicon, or the like) upon the sacrificial gate liner layer. The thickness of the sacrificial gate layer may be greater than the height of the one or more nanolayer stacks 120, 122, and/or 123. The sacrificial gate structure 134 may further be formed by subsequently forming a gate cap layer upon the sacrificial gate layer. The gate cap layer may be formed by depositing a mask material, such as a hard mask material, such as silicon nitride, silicon oxide, combinations thereof, or the like. The gate cap layer may be composed of one or more layers of masking materials to protect the sacrificial gate layer and/or other underlying materials during subsequent processing of semiconductor IC device 100.

The sacrificial gate structure 134 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 136, and the sacrificial gate cap 138, respectively, of each of the one or more sacrificial gate structures 134.

One or more sacrificial gate structure 134 can be formed on targeted regions or areas of semiconductor IC device 100 within the logic region to define the length of one or more GAA FETs, one or more GAA FET channels, or the like, and to provide sacrificial material for yielding targeted GAA FET structure(s) in subsequent processing. According to an example, each sacrificial gate structure 134 within the logic region can have a height of between approximately 50 nm and approximately 200 nm, and a length of between approximately 10 nm and approximately 200 nm.

One or more sacrificial gate structure 134 can be formed upon respective front and rear sides (e.g., out of the front of the paper, out of the back of the paper) of nanolayer stacks 120, 122, and/or 123 as wells as respective side surfaces of nanolayer stacks 120, 122, and/or 123, as depicted.

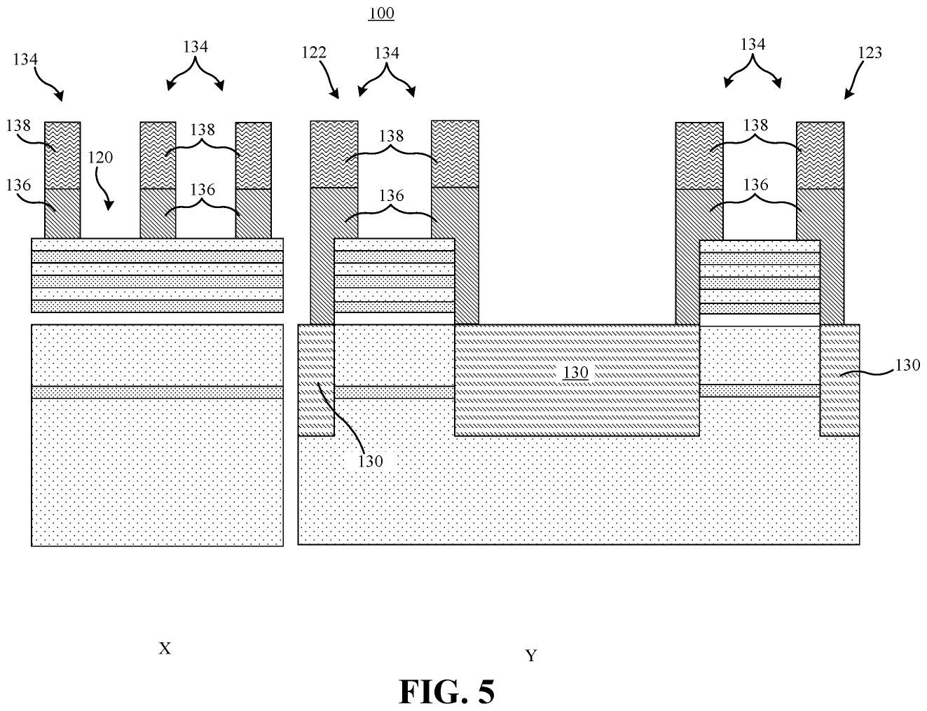

FIG. 5 depicts cross-sectional views of semiconductor IC device 100 shown after exemplary fabrication operation(s), in accordance with one or more embodiments. In the depicted fabrication stage, sacrificial nanolayer 104 may be selectively removed. The sacrificial nanolayer 104 may be the SiGe based layer with high Ge %, ranging from 50% to 70%, and/or material layer that is sufficiently different from the sacrificial nanolayers 106, active nanolayers 108, substrate 102, and/or sacrificial gate structures 134, such that the sacrificial nanolayer 104 can be selectively etched without also significantly removing the other features.

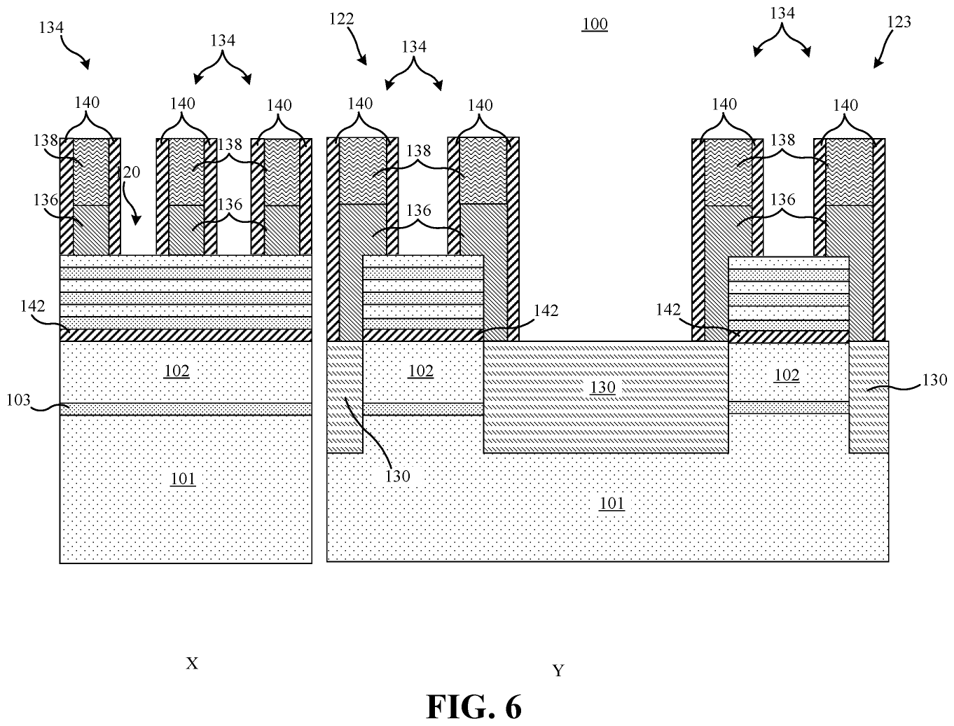

FIG. 6 depicts cross-sectional views of semiconductor IC device 100 shown after exemplary fabrication operation(s), in accordance with one or more embodiments. In the depicted fabrication stage, one or more bottom dielectric isolation (BDI) region(s) 142 may be formed in place of the removed sacrificial nanolayer 104 and one or more gate spacer(s) 140 may be formed. The BDI regions 142 and gate spacer(s) 140 may be respectively formed upon substrate 102, may be formed upon STI region(s) 130, may be formed upon and around nanolayer stacks 120, 122, and/or 123, and may be formed upon and around the one or more sacrificial gate structure(s) 134.

The BDI region(s) 142 may be formed upon the upper substrate 102 in the logic region between the nanolayers of the nanolayer stack(s) 120 and upper substrate 102 and upon the upper substrate 102 vertically between the nanolayers of the nanolayer stacks 122, 123 and the upper substrate 102. The BDI region(s) 142 may have a substantially horizontal orientation, as depicted.

Gate spacer(s) 140 may be formed around each of the one or more sacrificial gate structures 134, may be formed upon at least a portion of the sidewalls of the one or more nanolayer stack 120, 122, 123, and may be formed upon the top surface of portion(s) of the STI regions. In one example, gate spacers 140 and BDI regions 142 may be formed of relatively different dielectric material, such as silicon nitride, SiBCN, SiNC, SiN, SiCO, SiNOC, or the like.

Gate spacer(s) 140 and BDI regions 142 may be the same dielectric material, as depicted, and may be simultaneously formed by a deposition of a dielectric material, such as silicon nitride, SiBCN, SiNC, SiN, SiCO, SiNOC, or a combination thereof, or the like. Excess, undesired, and/or exposed dielectric material may be subsequently removed by a substrative removal technique, such as an etch.

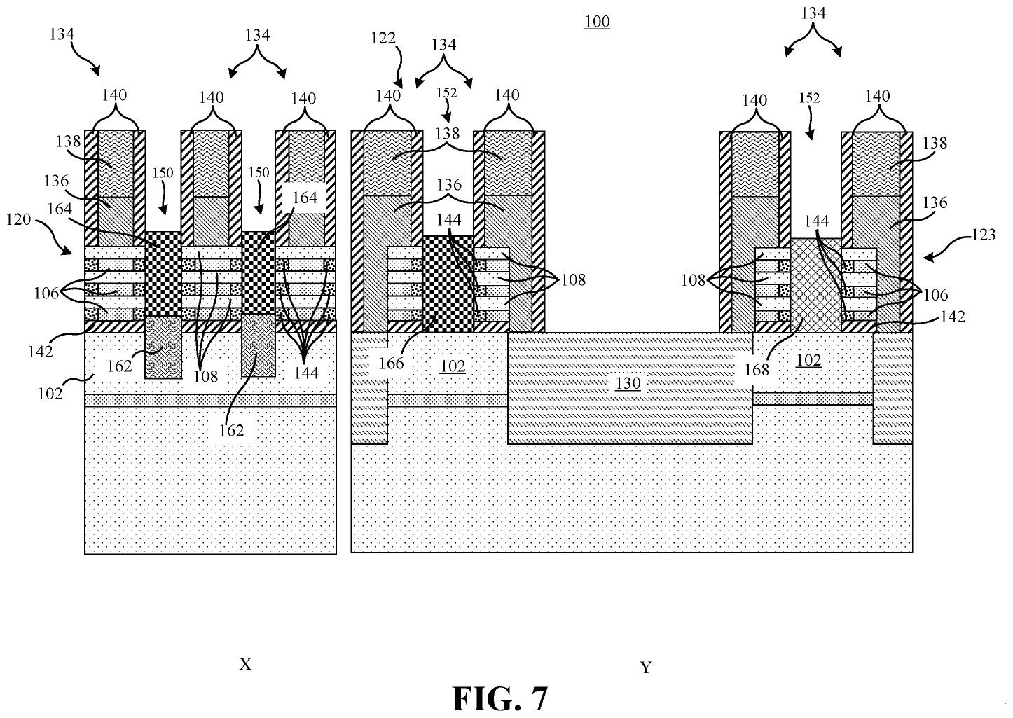

FIG. 7 depicts cross-sectional views of semiconductor IC device 100 shown after exemplary fabrication operation(s), in accordance with one or more embodiments. In the depicted fabrication stage, source/drain (S/D) recesses 150 are formed within the nanolayer stack 120 between spacers 140 associated with neighboring sacrificial gate structures 134 in the logic region and doped diode recesses 152 are formed within the nanolayer stacks 122, 123 between spacers 140 associated with neighboring sacrificial gate structures 134 in the diode region(s). Further, in the depicted fabrication stage, sacrificial nanolayers 106 within nanolayer stacks 120, 122, and/or 123 may be indented, thereby forming an indent void, and an inner spacer 144 may be formed within a respective indent void. Further in the fabrication stage, one or more backside contact placeholder(s) 162 are formed within upper substrate 102. Further, in the fabrication stage, source/drain regions 164, diode doped region 166, and diode doped region 168 are formed.

In the logic region, the one or more S/D recesses 150 may be formed between sacrificial gate structures 134 by removing sacrificial nanolayer(s) 106, by removing active nanolayer(s) 108, and by removing sacrificial nanolayer 104 that are between spacer(s) 140 of adjacent or neighboring sacrificial gate structures 134. The one or more S/D recesses 150 may be formed to a depth to stop at the upper substrate 102. The one or more S/D recesses 150 may be formed by removing undesired portions of the nanolayers, removing the portions of the nanolayers that are that are not protected by sacrificial gate structure 134 and/or by spacer(s) 140, or the like. These undesired portions of the nanolayers may be removed by etching or other subtractive removal techniques. The top surface of the STI region(s) 130 may be used as an etch stop. The retained one or more portions of one or more nanolayer stacks 120 may be such portions thereof that were protected generally below a sacrificial gate structure 134 and/or by the associated spacer(s) 140.

In the diode region(s), the diode recesses 152 may be formed between sacrificial gate structures 134 by removing sacrificial nanolayer(s) 106, by removing active nanolayer(s) 108, and by removing sacrificial nanolayer 104 that are between spacer(s) 140 of adjacent or neighboring sacrificial gate structures 134. The diode recesses 152 may be formed to a depth to stop at the upper substrate 102. The diode recesses 152 may be formed by removing undesired portions of the nanolayers, removing the portions of the nanolayers that are that are not protected by sacrificial gate structure 134 and/or by spacer(s) 140, or the like. These undesired portions of the nanolayers may be removed by etching or other subtractive removal techniques. The top surface STI region(s) 130 may be used as an etch stop. The retained one or more portions of one or more nanolayer stacks 122, 123 may be such portions thereof that were protected generally below a sacrificial gate structure 134 and/or by the associated spacer(s) 140.

The semiconductor IC device 100 may be subsequently subjected to a directional reactive ion etch (RIE) process, which can remove or indent portions of the sacrificial nanolayers 106 that are not covered by the sacrificial gate 136 and/or that are under the gate spacer(s) 140. The RIE can use a boron-based chemistry or a chlorine-based chemistry, for example, which selectively recesses the exposed portions sacrificial nanolayers 106 (e.g., those portions of sacrificial nanolayers 106 generally below spacer(s) 140, etc.) without substantially removing the active semiconductor nanolayers 108.

Subsequently, a respective inner spacer 144 may be deposited in the recess or indent that was previously formed into the sacrificial nanolayers 106. In certain embodiments, after the formation of the inner spacers 144, an isotropic etch process is performed to create outer vertical edges to the inner spacers 144 that align with outer vertical edges of the active semiconductor nanolayers 108. In certain embodiments, the material of the inner spacer 144 is a dielectric material such as SiN, SiO, SiBCN, SiOCN, SiCO, etc.

Further in the depicted fabrication stage, one or more backside contact placeholder(s) 162 are formed within the logic region within upper substrate 102. The one or more backside contact placeholder(s) 162 may be formed by initially forming one or more backside contact placeholder(s) cavities within the substrate generally between adjacent sacrificial gate structures 134 and underneath respective source/drain (S/D) locations in the logic region. For example, the one or more backside contact placeholder(s) cavities may be formed by a subtractive removal technique, such as an etch, that removes associated portion(s) of the substrate 102 within logic region. The etch may be timed or otherwise controlled to stop the removal of the substrate 102 within logic region such that the depth or bottom of the one or more backside contact placeholder(s) 162 is above the etch stop layer 103.

The one or more backside contact placeholder(s) 162 may be further formed by epitaxially growing an epitaxial material from exposed substrate 102 surface(s) within the one or more backside contact placeholder(s) cavities. In some embodiments, epitaxial growth and/or deposition processes may be selective to forming on the semiconductor surfaces of substrate 102, and may not deposit material on dielectric surfaces, such as silicon dioxide or silicon nitride surfaces. In some embodiments, the one or more backside contact placeholder(s)' 162 epitaxial growth may overgrow above the top surface of substrate 102. In an example, the sacrificial epitaxial material of the one or more backside contact placeholder(s) 162 may be chosen to be etch-selective to the material of the S/D region(s) 164, the material of substrate 102, or the like. In an example, the one or more backside contact placeholder(s) 162 may be bounded on each side by the upper substrate 102, as depicted, and may be bounded on the front and rear by respective one or more STI regions 130.

Further in the depicted fabrication stage, a S/D region 164 is formed upon a respective backside contact placeholder 162 within the logic region and diode region(s) 166 and diode region(s) 168 are formed within the diode region(s). The S/D region 164 forms either a source or a drain, respectively, to each associated or connected nanosheet GAA FET (i.e., those FETs in which the source or drain is connected to the active semiconductor nanolayers 108 channels) in the logic region. Diode region(s) 166 anddiode region(s) 168 forms a respective doped diode region(s).

The S/D region 164, the diode region(s) 166 and the diode region(s) 168 are respectively composed of a semiconductor material and a dopant. As used herein, a S/D region can be a source region or a drain region depending on subsequent wiring and application of voltages during operation of the transistor. The semiconductor material that provides each of the S/D region 164, the diode region(s) 166, and/or the diode region(s) 168 is composed of one of the semiconductor materials mentioned above for the semiconductor substrate. The semiconductor material that provides the S/D region 164, the diode region(s) 166, and/or the diode region(s) 168 can be compositionally the same, or compositionally different from each active nanolayers 108. The dopant that is present in the S/D region 164, the diode region(s) 166, and/or the diode region(s) 168 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contribute free electrons to an intrinsic semiconductor. In a silicon containing semiconductor material, examples of n-type dopants, i.e., impurities, include, but are not limited to, antimony, arsenic and phosphorous. In one example, each of the S/D region 164, the diode region(s) 166, and/or the diode region(s) 168 can have a dopant concentration of from 4×10²⁰ atoms/cm³ to 3×10²¹ atoms/cm³.

S/D regions 164, diode region(s) 166, and diode region(s) 168 may be epitaxially grown or formed. The S/D regions 164 may be formed by epitaxially growing epitaxial material upon a respective backside contact placeholder 162 within the logic region between neighboring nanosheet FETs. Diode region(s) 166 and diode region(s) 168 may be formed by epitaxially growing epitaxial material upon the upper substrate 102 between neighboring sacrificial gate structures 134.

In some examples, S/D regions 164, diode region(s) 166, and diode region(s) 168 are formed by in-situ doped epitaxial growth. In some embodiments, the S/D regions 164, diode region(s) 166, and diode region(s) 168 epitaxial growth may overgrow above the upper surface of the topmost active semiconductor nanolayer 108 within nanolayer stacks 120, 122, and/or 123.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions promote in-situ Boron doped SiGe for p-type transistor and phosphorus or arsenic doped silicon or Si:C for n-type transistors. The doping concentration in the S/D regions 164 can be in the range of 1×10¹⁹ cm³ to 2×10²¹ cm³, or preferably between 2×10²⁰ cm³ to 7×10²⁰ cm³.

In an example, diode region(s) 166 is a semiconductor material and can be highly doped with p-type doping with a doping concentration in the range of 1×10¹⁹ cm³ to 2×10²¹ cm³, or preferably between 2×10²⁰ cm³ to 7×10²⁰ cm³. Similarly, diode region(s) 168 is a semiconductor material with n-type doping with a doping concentration in the range of 1×10¹⁹ cm³ to 2×10²¹ cm³, or preferably between 2×10²⁰ cm³ to 7×10²⁰ cm³.

In certain implementations, the S/D regions 164, diode region(s) 166, and diode region(s) 168 may be partially recessed such that an upper portion of the S/D regions 164, diode region(s) 166, and/or diode region(s) 168 are removed. For example, the upper portion of the S/D regions 164, diode region(s) 166, and/or diode region(s) 168 may be etched or otherwise removed. The etch may be timed or otherwise controlled to stop the removal of S/D regions 164, diode region(s) 166, and/or diode region(s) 168 such that the top surface(s) thereof are above the upper surface of the topmost active nanolayer 108.

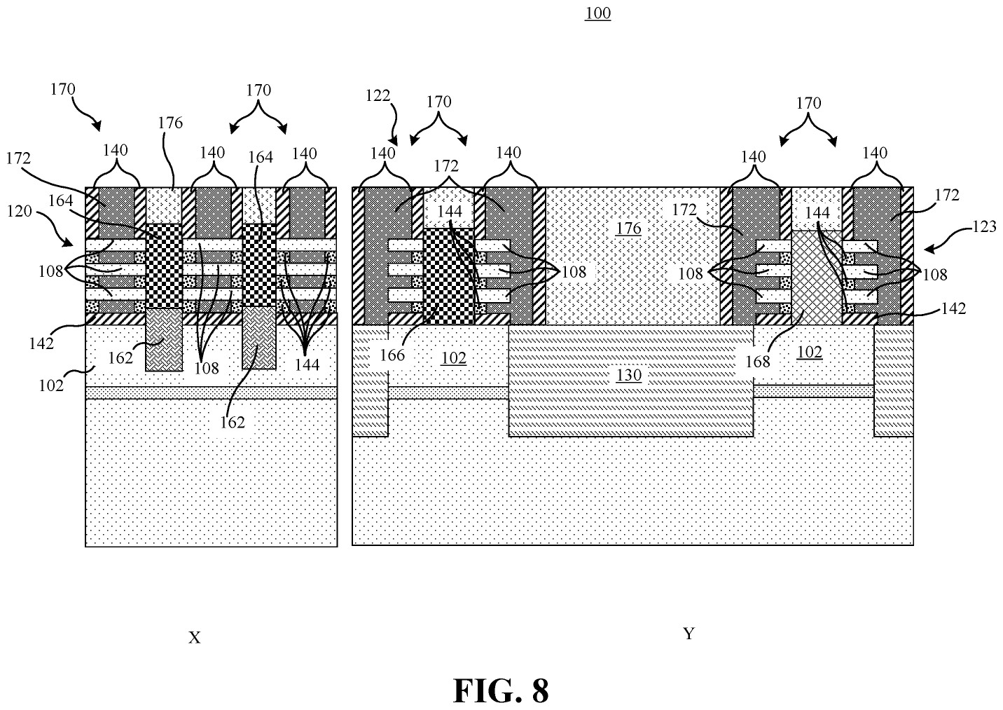

FIG. 8 depicts cross-sectional views of semiconductor IC device 100 shown after exemplary fabrication operation(s), in accordance with one or more embodiments. In the depicted fabrication stage, ILD 176 is formed upon S/D regions 164, diode region(s) 166, diode region(s) 168, and/or upon STI regions 130. Further in the depicted fabrication stage, sacrificial gate structures 134 are removed, the sacrificial nanolayers 106 are removed, and a replacement gate structure 170 is formed.

ILD 176 may be formed by depositing a dielectric material upon and around the S/D regions 164, upon STI region(s) 130, upon gate spacer(s) 140, or the like, within the logic region and within the Diode region(s). The ILD 176 can be any suitable material, such as, for example, porous silicates, carbon doped oxides, silicon dioxides, silicon nitrides, silicon oxynitrides, or other dielectric materials. In an example, the ILD 176 may be formed to a thickness so that the top surface of the ILD 176 is above the semiconductor IC device 100 and subsequently etched back such that the top surface of the ILD 176 is coplanar with a top surface of the sacrificial gate cap 138 and/or a top surface of gate spacer(s) 140. A planarization process, such as a chemical mechanical polish (CMP), may be performed to create a planar upper surface for the semiconductor IC device 100. In this example, the CMP may be performed to a depth to expose the sacrificial gate structure 134 (e.g., the sacrificial gate cap 138 may be removed).

Further in the depicted fabrication stage, the sacrificial gate structure(s) 134 are removed and a respective replacement gate structure 170 is formed in place of a respective sacrificial gate structure 134 within the logic region and within the diode region(s). The sacrificial gate structures 134 may be removed by removing associated portions of sacrificial gate cap 138 (if not already removed), sacrificial gate 136, sacrificial gate oxide (if present), and the sacrificial nanolayers 106 by a subtractive removal technique, such as one or more of etches. For example, removal of these features may be accomplished by an etching process which may include a dry etching process such as RIE, plasma etching, ion etching, or the like. The etching can further include a wet chemical etching process(es).

After the removal of sacrificial nanolayers 106, void spaces between the active semiconductor nanolayers 108 and/or BDI region 142 are formed. It should be appreciated that during the removal of the sacrificial gate 136, the sacrificial oxide layer, the sacrificial nanolayers 106, and/or the like, appropriate etchants are used that do not significantly remove material of active semiconductor nanolayers 108, substrate 102, inner spacers 144, BDI region 142, gate spacers 140, or the like. The dry and wet etching processes can have etching parameters that can be tuned, such as etchants used, etching temperature, etching solution concentration, etching pressure, source power, RF bias voltage, RF bias power, etchant flow rate, and other suitable parameters.

The replacement gate structure 170 may be formed by initially forming an interfacial layer (not shown) on the interior surfaces of the gate spacer(s) 140, on the interior surfaces of the active semiconductor nanolayers 108, on the inner spacers 140, on the BDI region 142, and on the STI region(s) 130, or the like. A high-κ layer (not shown) may be formed to cover the surfaces of exposed surfaces of the interfacial layer. The high-κ layer can be deposited by any suitable techniques, such as ALD, CVD, metal-organic CVD (MOCVD), physical vapor deposition (PVD), thermal oxidation, combinations thereof, or other suitable techniques. A high-κ material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, BaSrTiO₃ (BST), Al₂O₃, Si₃N₄, oxynitrides (SiON), or other suitable materials. The high-κ layer can include a single layer or multiple layers, such as metal layer, liner layer, wetting layer, and adhesion layer. In other embodiments, the high-κ layer can include, e.g., Ti, Ag, Al, TiAlN, TaC, TaCN, TaSiN, Mn, Zr, TiN, TaN, Ru, Mo, Al, WN, Cu, W, or any suitable materials.

Replacement gate structure 170 may be further formed by depositing a work function (WF) gate (not shown) upon the high-κ layer. The WF gate can be comprised of metals, such as, e.g., copper (Cu), cobalt (Co), aluminum (Al), platinum (Pt), gold (Au), titanium (Ti), or any combination thereof. The metal can be deposited by a suitable deposition process, for example, chemical vapor deposition (CVD), plasma enhanced chemical vapor deposition (PECVD), physical vapor deposition (PVD), plating, thermal or e-beamF evaporation, or sputtering. In general, the work function (WF) gate sets the threshold voltage (Vt) of the transistors associated with the active semiconductor nanolayers 108 within the logic region. The high-κ layer can separate the WF gate and the active semiconductor nanolayers 108. The WF gate may be formed to a thickness to generally fill the gaps or voids between active semiconductor nanolayers 108.

Replacement gate structure 170 may be further formed by depositing a conductive fill gate 172 upon the WF gate. The conductive fill gate 172 can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP. Subsequently, the respective top surfaces of gate spacers 140, replacement gate structures 170, ILD 176, or the like, may be substantially horizontal and or substantially coplanar.

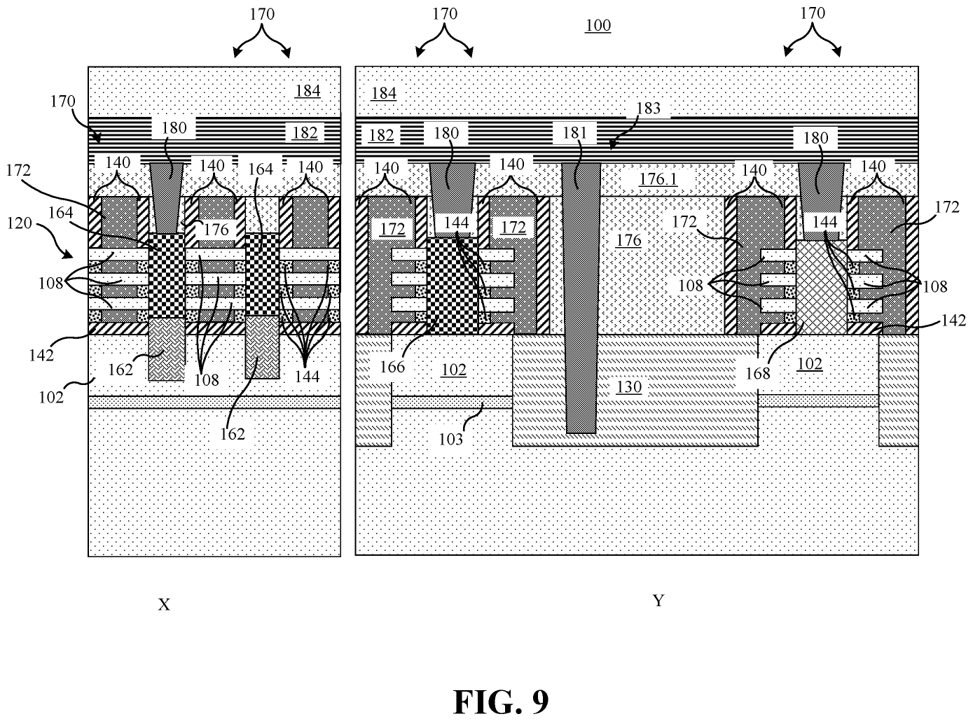

FIG. 9 depicts cross-sectional views of semiconductor IC device 100 shown after exemplary fabrication operation(s), in accordance with one or more embodiments. In the depicted fabrication stage, an ILD 176.1 is formed, a respective frontside contact 180 is formed upon one or more S/D regions 164, upon diode region(s) 166, and upon diode region(s) 168. Further in the depicted fabrication stage, a conductive pathway 183 is formed, a frontside BEOL network 182 is formed, and a carrier wafer 184 is bonded thereto.

The ILD 176.1 may be formed upon the top surface of ILD 176, upon the top surface of gate spacer(s) 140, upon the top surface of replacement gate structure(s) 170, and/or the like. The ILD 176.1 may be formed by depositing a dielectric material, such as, for example, porous silicates, carbon doped oxides, silicon dioxides, silicon nitrides, silicon oxynitrides, or other dielectric materials. Any known manner of forming the ILD 176.1 can be utilized. The ILD 176.1 can be formed using, for example, CVD, PECVD, ALD, flowable CVD, spin-on dielectrics, or PVD. The ILD 176.1 may be the same or different material relative to ILD 176.

Subsequently, front-side contact openings are formed within ILD 176.1. The formation of front-side contact openings may include etching the ILD 176.1 to form the openings. A respective opening may expose at least a portion of S/D region 164, at least a portion of diode region(s) 166, and/or at least a portion of diode region(s) 168. Frontside contacts 180 may be formed by depositing conductive material within the front-side contact openings. The formation of the frontside contacts 180 may include forming a blanket conductive barrier layer extending into the front-side contact openings, depositing a metal or conductive material over the blanket conductive barrier layer, and performing a planarization process, such as a CMP process or a mechanical grinding process, to remove excess portions of the conductive barrier layer and the conductive material. Frontside contacts 180 may consist of a liner formed of Ni, NiPt, Ti, TiN, TaN, etc. and a conductive fill thereupon, such as Al, Ru, W, Co, Cu, etc. In some implementations, the formation of frontside contacts 180 may be a part of middle of the line (MOL) fabrication processes.

A respective frontside contact 180 may contact or otherwise meld to the exposed portion of the S/D region 164, of the diode region(s) 166, and of the diode region(s) 168. The respective frontside contact 180 located in the logic region, as depicted, may contact or otherwise meld to the exposed portion of the S/D region 164 and provide power potential (VDD, VSS, or the like) thereto. In the logic region, another respective frontside contact (not shown) may contact or otherwise meld to the replacement gate structure. This gate contact may be further connected to a signal line and electrically carry a functional or logical potential or signal that is to change or is otherwise dynamic over time. Such functional or logical potential or signal may determine whether the associated transistor is on or off.

A frontside contact 180, located in the diode region, as depicted, may contact or otherwise meld to the exposed portion of the diode region 166. Similarly, a frontside contact 180, located in the diode region, as depicted, may contact or otherwise meld to the exposed portion of the diode region 168.

A front-side deep contact opening may be formed within ILD 176.1, within ILD 176, and within the STI region 130. In an example, the front-side deep contact opening may be simultaneously formed along with the frontside contact openings discussed above. The formation of front-side deep contact opening may include etching to form the openings. A respective opening may expose at least a portion of STI region 130. Conductive pathway 183, such as a deep via contact 181, may be formed by depositing conductive material within the front-side deep contact opening. The formation of the conductive pathway 183 may include forming a blanket conductive barrier layer extending into the front-side contact openings, depositing a metal or conductive material over the blanket conductive barrier layer, and performing a planarization process, such as a CMP process or a mechanical grinding process, to remove excess portions of the conductive barrier layer and the conductive material. Conductive pathway 183, such as a deep via contact 181, may consist of a liner formed of Ni, NiPt, Ti, TiN, TaN, etc. and a conductive fill thereupon, such as Al, Ru, W, Co, Cu, etc. In some implementations, the formation of conductive pathway 183, such as a deep via contact 181, may be a part of middle of the line (MOL) fabrication processes.

Conductive pathway 183, such as deep via contact 181, may extend to be within STI region(s) 130. For example, a bottom surface of the conductive pathway may be below the bottom surface of etch stop layer 103.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. The frontside contact(s) 180 and conductive pathway 183 may be a part of the MOL.

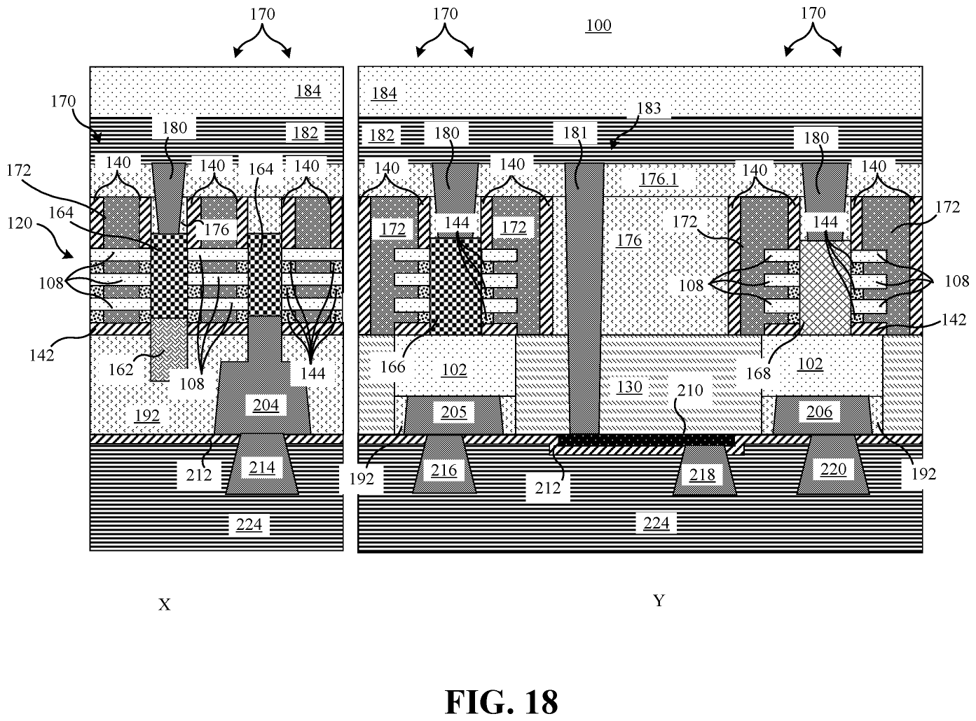

BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network 182 is formed on the frontside of the semiconductor device 100. Subsequently, a backside BEOL network 224, as depicted in FIG. 18 is formed.

In the depicted example, the frontside BEOL network 182 is formed over the ILD 176.1 and upon the frontside contact(s) 180. Respective wires within the frontside BEOL network 182 may be electrically connected to the one or more S/D regions 164, one or more replacement gate structure(s) 170, one or more diode region(s) 166, and/or one or more diode region(s) 168, by a respective frontside contact 180. The frontside BEOL network 182 is located directly on the frontside surface of the MOL structure (e.g., ILD 176.1, frontside contacts 180, etc.). The frontside BEOL network 182 can include one or more interconnect dielectric material layers (including one of the dielectric materials mentioned above for the frontside ILD 176) and contains frontside metal wires (the metal wires can be composed of any electrically conductive metal or electrically conductive metal alloy) embedded therein. In some embodiments, the frontside metal wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the metal wires and may be used to connect the semiconductor IC device to an external and/or higher-level structure, such as a chip carrier, motherboard, or the like.

The carrier wafer 184 can include one of the semiconductor materials mentioned above for the semiconductor structure. Carrier wafer 184 may be attached to the semiconductor IC device 100 by a wafer-to-wafer bonding technique.

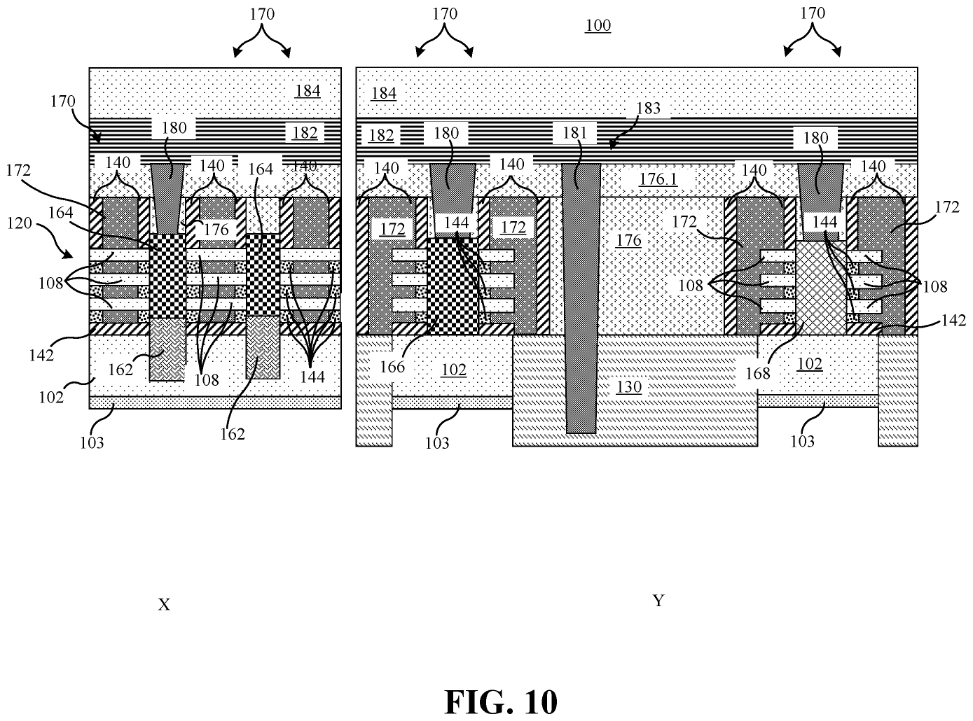

FIG. 10 depicts cross-sectional views of semiconductor IC device 100 shown after exemplary fabrication operation(s), in accordance with one or more embodiments. In the depicted fabrication stage, semiconductor IC device 100 is flipped (not shown) and lower substrate 101 is removed. The lower substrate 101 may be removed by any removal technique, such as a combination of wafer grinding, CMP, dry etch and wet etch. In the example depicted, lower substrate 101 is removed by an etch that utilizes etch stop layer 103 as the etch stop. In this example, removal of lower substrate 101 exposes the bottom surface of etch stop layer 103.

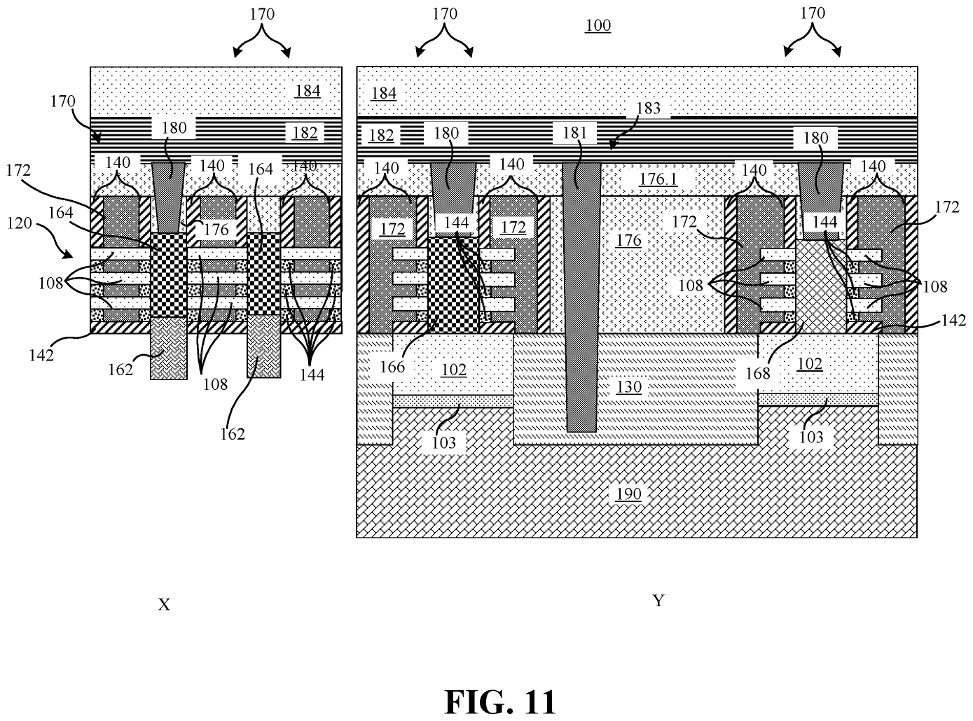

FIG. 11 depicts cross-sectional views of semiconductor IC device 100 shown after exemplary fabrication operation(s), in accordance with one or more embodiments. In the depicted fabrication stage, the diode region(s) are protected by forming a mask 190 thereupon and the etch stop layer 103 and the upper substrate 102 within the logic region is removed.

The mask 190 may be formed by depositing a blanket dielectric material or other mask material upon the etch stop layer 103 and upon STI regions 130. Using lithography and etching techniques, the blanket layer located in the diode region(s) may be protected and the blanket layer located in the logic region may be exposed and removed. The remaining portions of the blanket layer may form the mask 190 within the diode region(s). In other examples, the mask 190 may be formed directly, selectively, or, in other words, only within the diode region(s). The mask 190 can be any suitable material, such as, for example, porous silicates, oxides, nitrides, silicon oxynitrides, an organic planarization layer (OPL), or other dielectric materials. The mask 190 can be formed using, for example, CVD, PECVD, ALD, flowable CVD, spin-on dielectrics, PVD, or the like.

Using the mask 190 to protect the diode region(s), the upper substrate 102 within the logic region is removed by an appropriate substrative removal technique, such as an etch, that removes associated portion(s) of etch stop layer 103 and substrate 102 within logic region. One etch or a series of etches each may be timed or otherwise controlled to remove the etch stop layer 103 and the upper substrate 102 within logic region and retain or otherwise expose the backside contact placeholder(s) 162 and BDI region(s) 142, or the like.

Subsequently, the mask 190 may be removed from the diode region(s) by an etch, OPL ash, or the like, and the etch stop layer 103 may be removed within the diode region(s) by a subtractive removal technique such as a CMP, dry and/or wet etch. Upon removal of the etch stop layer 103, the bottom surface (as depicted) of upper substrate 102 is exposed.

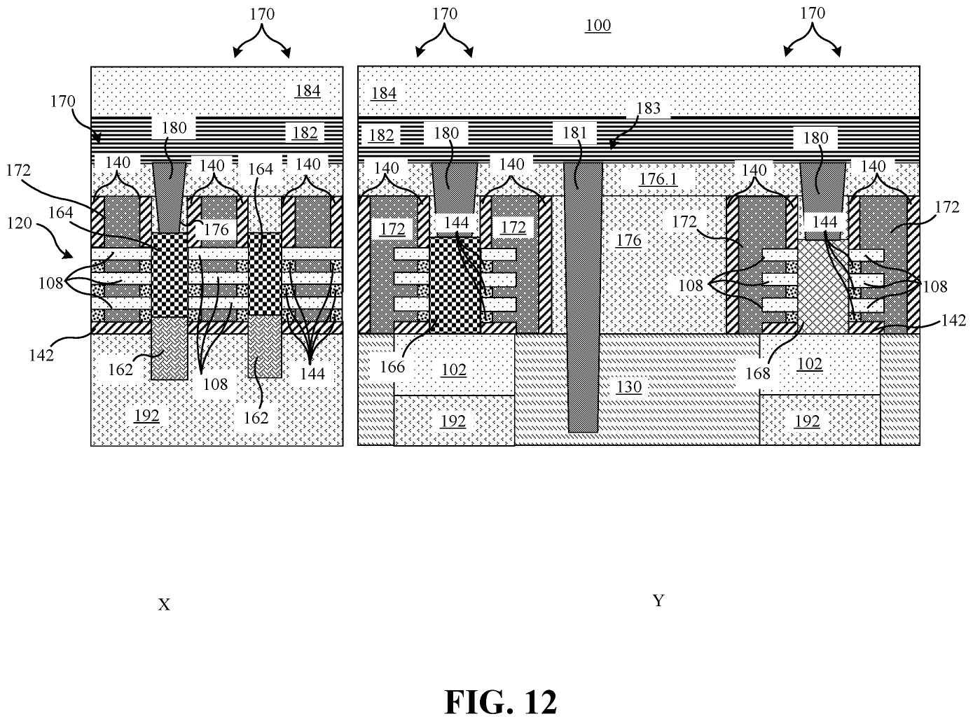

FIG. 12 depicts cross-sectional views of semiconductor IC device 100 shown after exemplary fabrication operation(s), in accordance with one or more embodiments. In the depicted fabrication stage, backside ILD 192 is formed within the logic region and within the diode region(s). The backside ILD 192 may be formed upon the bottom surfaces (as depicted) of BDI region(s) 142, upon and around the backside contact placeholder(s) 162, upon the bottom surfaces (as depicted) of STI region(s) 130, and/or upon the bottom surface (as depicted) of upper substrate 102. The backside ILD 192 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 192 can be utilized. The backside ILD 192 can be formed using, for example, CVD, PECVD, ALD, flowable CVD, spin-on dielectrics, or PVD.

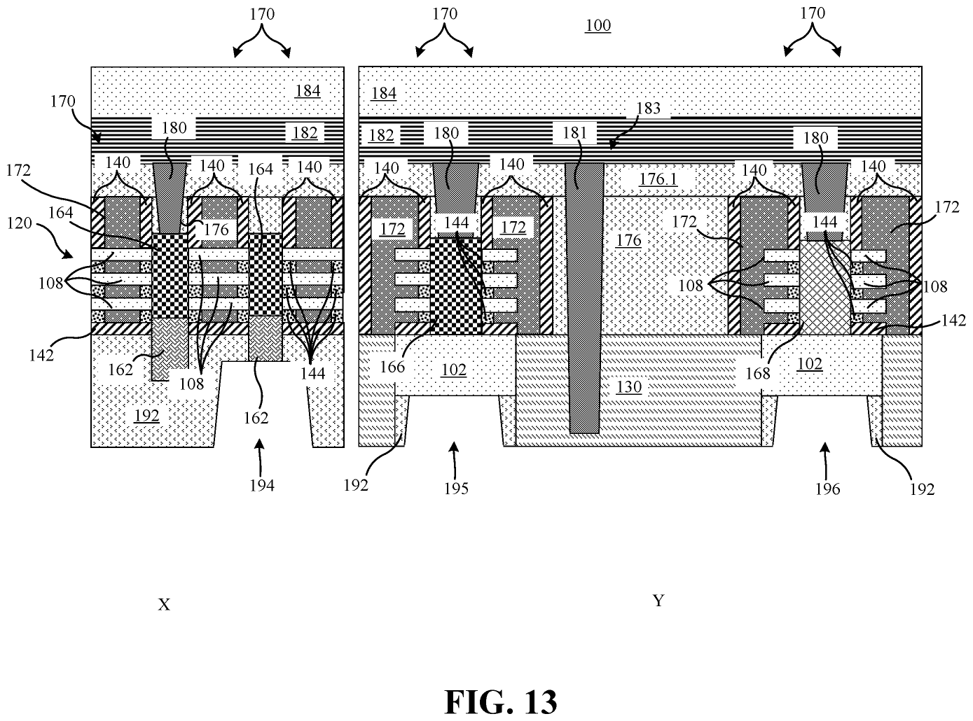

FIG. 13 depicts cross-sectional views of semiconductor IC device 100 shown after exemplary fabrication operation(s), in accordance with one or more embodiments. In the depicted fabrication stage, a backside contact opening 194 may be formed within the logic region and a backside contact opening 195 and a backside contact opening 196 may be formed within the diode region(s).

The backside contact opening(s) 194 are formed from the backside of the semiconductor IC device 100 through backside ILD 192 within the logic region and may expose a portion of the bottom surface and/or side surface(s) of a respective backside contact placeholder 162. The backside contact opening 195 is formed from the backside of the semiconductor IC device 100 through backside ILD 192 within the diode region(s) and may expose a portion of the bottom surface (as depicted) of the upper substrate and may be horizontally in line with diode region 166. The backside contact opening 196 is formed from the backside of the semiconductor IC device 100 through backside ILD 192 within the diode region(s) and may expose a portion of the bottom surface of the upper substrate 102 and may be horizontally in line with diode region 168.

The backside contact openings 194, 195, and/or 196 may be formed by a subtractive removal technique, such as an etch, that removes associated portion(s) of the backside ILD 192. The etch may be timed or otherwise controlled to stop the removal of the backside ILD 192 in the logic region such that the depth or bottom of backside contact openings 194 exposes the bottom and/or side surfaces of the associated backside contact placeholder 162 and to stop the removal of the backside ILD 192 in the diode region(s) such that the depth or bottom of backside contact openings 195, 196 exposes the bottom surfaces of the associated upper substrate 102 region.

The backside contact openings 194, 195, and/or 196 may be formed by the same or shared lithography and etch process, or sequential lithography and etch processes. In such process(es), a mask may be applied and patterned. An opening in the patterned mask may expose the portion of the underlying backside ILD 192 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, and other suitable parameters and selective materials are utilized to promote the etchant for desired material removal.

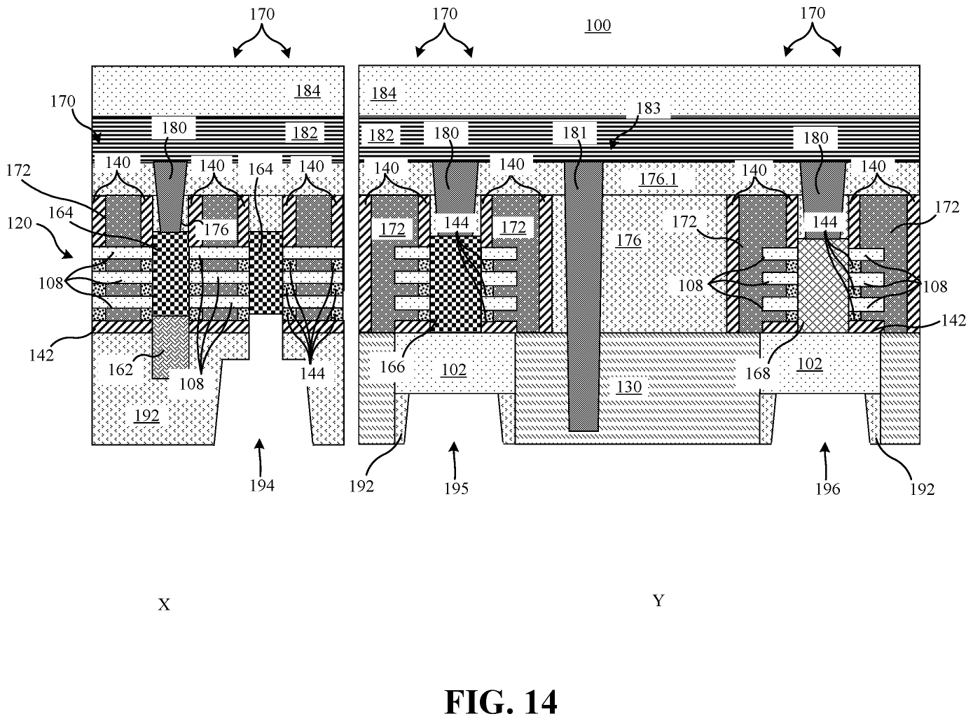

FIG. 14 depicts cross-sectional views of semiconductor IC device 100 shown after exemplary fabrication operation(s), in accordance with one or more embodiments. In the depicted fabrication stage, one or more of respective backside contact placeholder(s) 162 that are exposed by backside contact openings 194 may be removed. Upon removal of the backside contact placeholder(s) 162 by a substrative removal technique, such as an etch, the S/D region 164 thereabove is at least partially exposed.

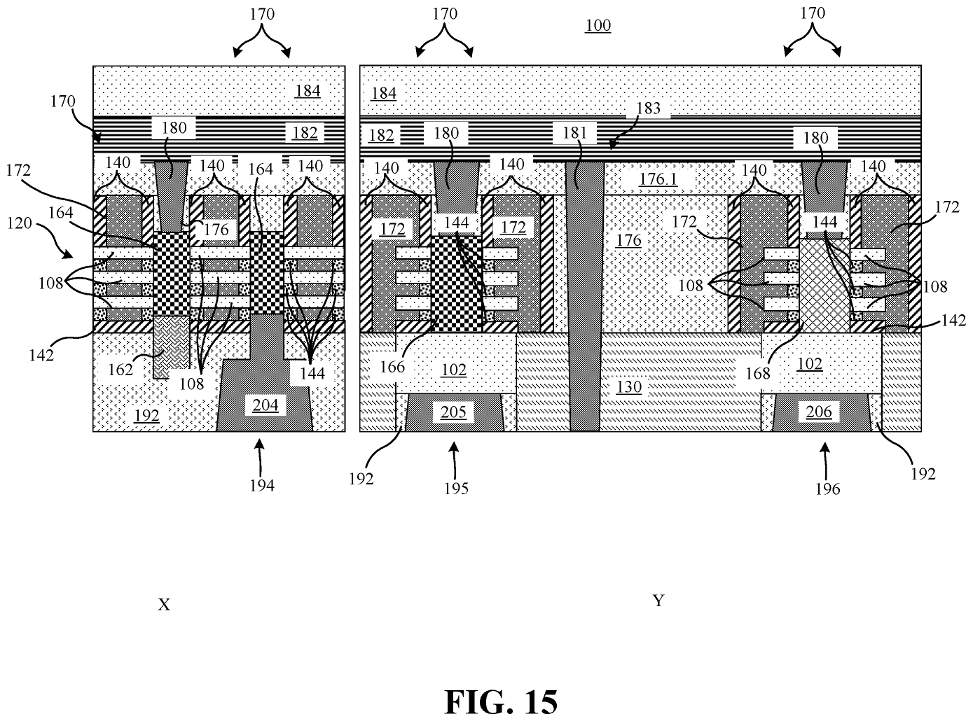

FIG. 15 depicts cross-sectional views of semiconductor IC device 100 shown after exemplary fabrication operation(s), in accordance with one or more embodiments. In the depicted fabrication stage, one or more of respective backside contact placeholder(s) 162 that are exposed by backside contact openings 194 may be removed.

Further in the depicted fabrication stage, backside contact 204 may be formed within the logic region, backside contact(s) 204 may be formed within the logic region, backside contact 205 and backside contact 206 may be formed within the diode region(s).

The backside contact 204 may be formed in contact with or melded against the exposed portion of the S/D region 164 thereabove. The backside contact 205 may be formed in in contact with or melded against the exposed portion of the upper substrate 102 region thereabove and the backside contact 206 may be formed in in contact with or melded against the exposed portion of the upper substrate 102 region thereabove.

The backside contacts 204, 205, and/or 206 may be formed by depositing conductive material, such as metal into the respective backside contact openings. In an example, the backside contacts 204, 205, and/or 206 may be formed by depositing a liner, such as Ni, NiPt or Ti, etc. into the backside contact openings, depositing a metal adhesion liner, such as TiN, TaN, etc. upon the liner, and by depositing a conductive metal fill, such as Al, Ru, W, Co, Cu, etc. upon the metal adhesion liner.

Subsequently, a planarization process, such as a CMP process or a mechanical grinding process, may remove excess portions of the conductive barrier layer and the conductive material. The planarization process may also expose the conductive pathway 183. For example, a bottom surface of the deep via contact 181 may be exposed by the planarization process. Subsequently, the respective bottom surfaces (as depicted) of backside contacts 204, 205, and/or 206, the backside ILD 192, and the conductive pathway 183 may be coplanar.

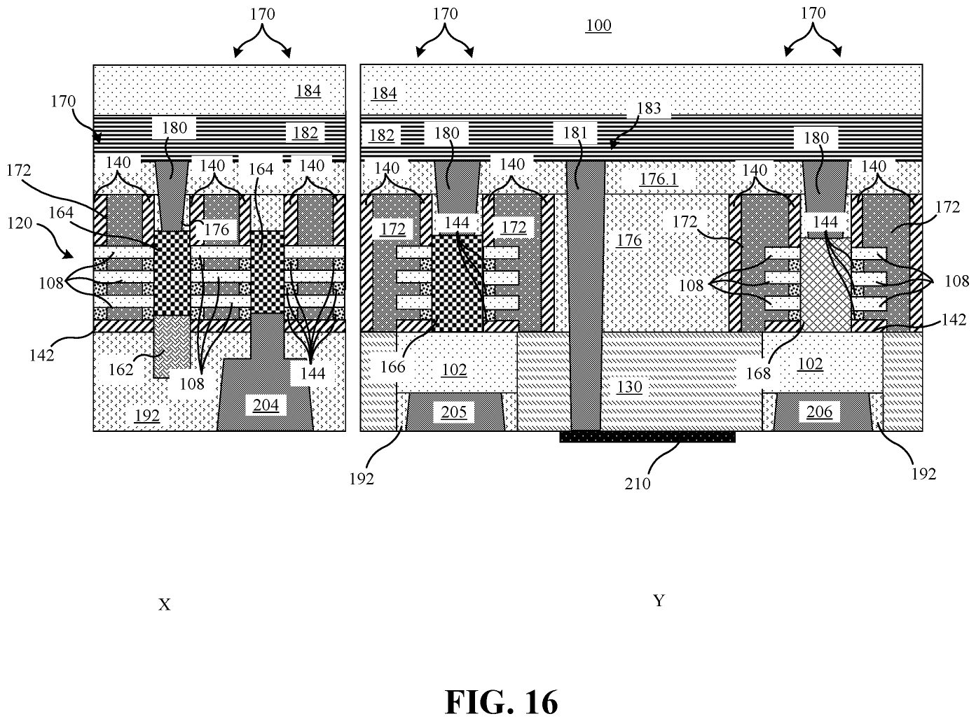

FIG. 16 depicts cross-sectional views of semiconductor IC device 100 shown after exemplary fabrication operation(s), in accordance with one or more embodiments. In the depicted fabrication stage, backside resistor 210 is formed within a resistor region. The backside resistor 210 is formed upon the respective bottom surfaces of the STI region(s) 130, and the conductive pathway.

Backside resistor 210 is formed of conductive material and may be formed by a deposition process such as CVD, plating, or the like. The backside resistor 210 may be formed by lithography and etch process(es). In such process(es), a mask may be applied and patterned. Backside wire opening(s) in the patterned mask may expose the respective locations upon the STI region 130 and the conductive pathway 183 to which the backside resistors 210 are to be formed while other protected portions of semiconductor IC device 100 thereunder may be protected from backside resistor 210 formation thereupon.

The backside resistor 210 may be further formed by depositing conductive material such as metal into the respective backside wire opening(s). In an example, the backside resistor 210 may be formed by depositing a conductive metal, such as TiN, WSix, Al, Ru, W, Co, Cu, etc. within the backside wire opening(s). Subsequently, a substrative removal technique, such as an etch or series of etches, may remove excess portions of the conductive material and the shared mask.

The conductive material and/or geometry of backside resistor 210 (e.g., length, cross-sectional area across the length, or the like) may be chosen to achieve a predetermined resistance across the backside resistor 210. In one embodiment, each backside resistor 210 within the resistor region may share the same geometry. However, in other examples, the backside resistors 210 within the resistor region may have different geometries, each chosen to achieve its predetermined resistance to enable, or aide, predetermined semiconductor IC device 100 operations. In a particular embodiment, the conductive material of the backside resistor 210 is different relative to the conductive material of the conductive pathway 183, deep via contact 181, backside contacts 204, 205, 206, and/or the frontside contacts 180. Further, the conductive material of the backside resistor 210 may be different relative to the conductive material of the metal within the frontside BEOL network 182 and/or the backside BEOL network 224, shown in FIG. 18. This allows for the backside resistor 210 to have a relatively higher or lower respective resistance relative to such other conductive materials, to achieve the predetermined resistance of the backside resistor 210.

Backside resistor 210 may be located vertically between the backside BEOL network 224 (e.g., shown in FIG. 18) and the one or more FEOL microdevices (e.g., one or more GAA FETs, one or more diodes, or the like). A first end surface of backside resistor 210 may be horizontally inset relative to a predetermined backside contact 205, as depicted. Similarly, a second end surface of backside resistor 210 may be horizontally inset relative to a predetermined backside contact 206, as depicted. This may positionally allow for the conductive pathway 183 and the backside resistor 210 to be located between the first diode associated with backside contact 205 and the adjacent second diode associated with backside contact 206.

Because backside resistor 210 may fabricated upon the planarized bottom surface of the semiconductor IC device 100 of FIG. 16, the bottom surface of backside resistor 210 may be below the bottom surface of the backside contact 205 and/or 206 (as depicted). Similarly, the top surface of backside resistor 210 may be substantially coplanar with the bottom surface of the backside contact 205 and/or 206 (as depicted).

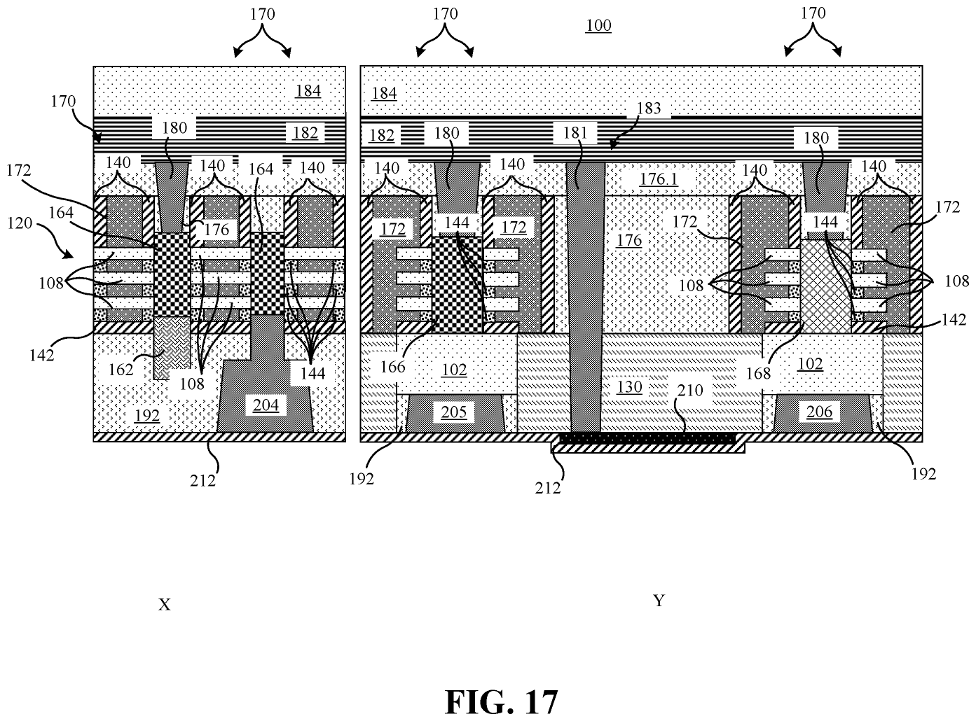

FIG. 17 depicts cross-sectional views of semiconductor IC device 100 shown after exemplary fabrication operation(s), in accordance with one or more embodiments. In the depicted fabrication stage, backside capping layer 212 is formed upon the exposed backside of the semiconductor IC device 100.

The backside capping layer 212 may be formed upon the bottom surfaces (as depicted) of the STI region(s) 130, upon the bottom surfaces (as depicted) one or more backside contacts 204, 205, and/or 206, and upon and around the backside resistor 210. The backside capping layer 212 may be formed by depositing a dielectric material, such as, for example, porous silicates, carbon doped oxides, silicon dioxides, silicon nitrides, silicon oxynitrides, or other dielectric materials.

Any appropriate deposition technique for forming the backside capping layer 212 can be utilized. The backside capping layer 212 can be formed using, for example, CVD, PECVD, ALD, flowable CVD, spin-on dielectrics, or PVD. In a particular embodiment, the backside capping layer 212 may be a different material relative to the backside ILD 192. For example, the backside capping layer 212 may be a silicon nitride and the backside ILD 192 may be a silicon dioxide. In an example, the backside capping layer 212 has a vertical thickness ranging, for example, from approximately 3 nm to approximately 20 nm. In certain embodiments, the backside capping layer 212 has a vertical thickness ranging, for example, from approximately 3 nm to approximately 10 nm.

FIG. 18 depicts cross-sectional views of semiconductor IC device 100 shown after exemplary fabrication operation(s), in accordance with one or more embodiments. In the depicted fabrication stage, a backside BEOL network 224 is formed.

The backside BEOL network 224 is formed over the backside capping layer 212 and upon the one or more backside contacts 204, 205, and/or 206. The backside BEOL network 224 may be indirectly electrically and/or indirectly physically connected to the one or more S/D regions 164 by way of a particular backside contact 204. The backside BEOL network 224 may be indirectly electrically and/or indirectly physically connected the first diode by way of a particular backside contact 205. Similarly, the backside BEOL network 224 may be indirectly electrically and/or indirectly physically connected the second diode by way of a particular backside contact 206. The backside BEOL network 224 is located directly on the backside surface of capping layer 212, backside contacts 204, 205, and/or 206, etc.

The backside BEOL network 224 can include one or more interconnect dielectric material layers (including one of the dielectric materials mentioned above for the ILD layer 176) and contains backside metal wires embedded therein. In some embodiments, the backside metal wires within the backside BEOL network 224 are composed of Cu. The backside BEOL network 224 can include “x” numbers of backside metal levels, wherein “x” is an integer starting from 1. If not included in frontside BEOL network 182, backside BEOL network 224 may further contain conductive pads that are connected to one or more of the backside metal wires and may be used to connect the semiconductor IC device 100 to the external and/or higher-level structure.

In an example, signal routing and power routing is effectively split between the frontside BEOL network 182 and the backside BEOL network 224. For example, at least 90% of the frontside metal wires (e.g., furthest from the transistor(s)) are signal routing metal wires and the remainder frontside metal wires which are usually present in metal levels closest to the microdevices within the FEOL, can be used as power routing wires. Further in this example, at least 90% of the backside metal wires that are in metal levels closest to the microdevices within the FEOL are power routing metal wires and the remainder backside metal wires which are usually present in metal levels furthest away from the transistor, can be used as signal routing wires. Power routing wires may be less dense signal routing wires. A signal routing wire is defined herein as a conductive feature, such as a wire, trace, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, in some examples, the backside BEOL network 224 may be a backside power distribution network (BSPDN).

The backside BEOL network 224 includes various wiring levels. The wiring levels may alternate between a via level and a metal level. To form a via level, an associated dielectric passivation layer may be formed, the dielectric passivation layer may be patterned to create a via opening therein, and conductive or metal material may be deposited within the via opening to form a via contact. A via, such as via contacts 214, 216, 218, and/or 220, within a lowest via level may connect either directly or indirectly to an associated structure. For example, via contact 214 may directly connect to backside contact 204, via contact 216 may directly connect to backside contact 205, via contact 218 may directly connect to backside resistor 210, and via contact 220 may directly connect to backside contact 206.

To form a metal level, an associated dielectric passivation layer may be formed, the dielectric passivation layer may be patterned to create a wiring trench therein, and conductive or metal material may be deposited within the wiring trench to form a wire. A wire within a lowest metal level may connect directly one or more via contacts, such as via contacts 214, 216, 218, and/or 220. For clarity, a conductive pathway within the backside BEOL network 224 may be formed and may be directly connected to via contact 218. The electrical pathway may include contact vias (in the same or different level), multiple wires (in the same or different levels), or the like and be located in higher levels, be located within multiple levels, or the like.

For clarity, semiconductor IC device 100 includes a conductive structure that consists of the conductive pathway 183 and the backside resistor 210 that may route current or be a potential node (VSS node, VDD node, etc.) between backside BEOL network 224 and frontside BEOL network 182. The conductive pathway 183 may be a deep via contact 181 or other through conductor structure or through semiconductor structure, such as a heavily doped region. The backside resistor 210 is located vertically between the FEOL microdevices (e.g., GAA FETs, diodes, or the like) and the backside BEOL network 224. In a particular example, a bottom surface of the conductive pathway 183 is directly connected to the top surface of the backside resistor 210 and a bottom surface of the backside resistor 210 is electrically connected to a backside BEOL network 224 contact, such as via contact 218.

The conductive structure that consists of the conductive pathway 183 and the backside resistor 210 may route current between the frontside BEOL network 182 and the backside BEOL network 224 for FEOL microdevice operations. For instance, the conductive structure that consists of the conductive pathway 183 and the backside resistor 210 may be electrically connected.

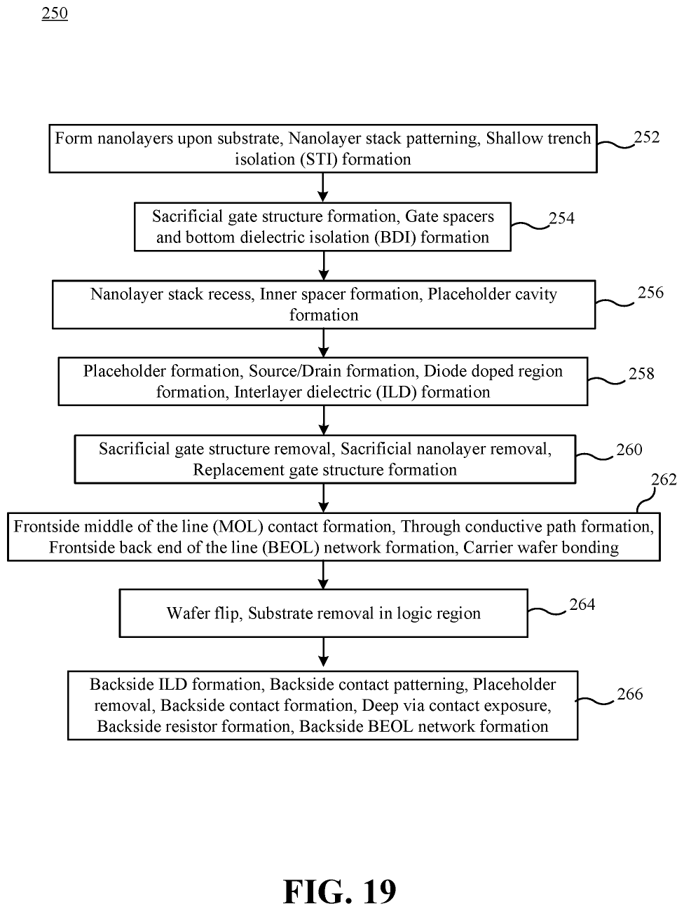

FIG. 19 depicts a flow diagram illustrating a method to fabricate the semiconductor IC device 100 that includes a backside resistor 210, according to one or more embodiments of the present disclosure. The depicted fabrication operations of method 250 are illustrated and described above with reference to one or more of FIG. 1 through FIG. 18 of the drawings. The method 250 depicted herein is illustrative and there can be many variations to the diagram or operations described therein without departing from the spirit of the embodiments. For instance, the operations can be performed in a differing order, or operations can be added, deleted, or modified.

At block 252, method 250 may begin with forming nanolayers upon a substrate, patterning the nanolayers into one or more nanolayer stacks, and forming one or more STI region(s). For example, method 250 may include initially fabricating a sacrificial nanolayer 104 upon upper substrate 102. Next, an alternating series of sacrificial nanolayers 106 and active nanolayers 108 may be formed upon the sacrificial nanolayer 104. Further, method 250 may include pattering the nanolayers to form one or more nanolayer stack(s) 120 in the logic region and pattering the nanolayers into nanosheet stack 122 and nanosheet stack 123 in the diode region(s). Further, method 250 may include forming STI region(s) 130 within the upper substrate 102 next to, and/or that separate, the nanolayer stacks 120, 122, and/or 123.

At block 254, method 250 may further continue with forming one or more sacrificial gate structure(s), forming one or more gate spacers upon the one or more sacrificial gate structure(s), and with forming a BDI region(s). For example, method 250 may include forming one or more sacrificial gate structures 134 upon the STI region(s) 130 and upon and around the nanolayer stacks 120, 122, and/or 123. Further, method 250 may include removing sacrificial nanolayer 104. Further, method 250 may include forming one or more BDI region(s) 142 in place of the removed sacrificial nanolayer 104 and with forming one or more gate spacer(s) 140 upon the sidewall(s) of the sacrificial gate structures 134. The BDI region(s) 142 and spacer(s) 140 may be respectively formed upon the upper substrate 102, may be formed upon STI region(s) 130, may be formed upon and around nanolayer stacks 120, 122, and/or 123, and may be formed upon and around the one or more sacrificial gate structure(s) 134, respectively.

At block 256, method 250 may further continue with recessing or indenting the sacrificial nanolayers within the nanolayer stacks, with forming a respective inner spacer within the recesses or indent, and with forming a placeholder cavity. For example, method 250 may include forming S/D recesses 150 within the nanolayer stack 120 between spacers 140 associated with neighboring sacrificial gate structures 134 in the logic region and forming diode recesses 152 within the nanolayer stacks 122, 123 between gate spacers 140 associated with neighboring sacrificial gate structures 134 in the diode region(s). Further, method 250 may include, from the formed recesses, indenting the sacrificial nanolayers 106 within nanolayer stacks 120, 122, and/or 123, thereby forming an indent void. Method 250 may further include forming an inner spacer 144 within a respective indent void.

At block 258, method 250 may further continue with forming one or more backside contact placeholder structures, with forming one or more S/D regions within the logic region, with forming one or more diode doped region(s) within the diode region(s), and with forming an ILD within the logic region and within the diode region(s). For example, method 250 may include forming or more backside contact placeholder(s) 162 within the upper substrate 102 in the logic region. Further, method 250 may include forming a S/D region 164 upon a respective backside contact placeholder 162 within the logic region and with forming doped diode region(s) 166 and doped diode region(s) 168 within the diode region(s). Still further, method 250 may include forming ILD 176 upon S/D regions 164, doped diode region(s) 166, doped diode region(s) 168, and/or upon the STI region(s) 130.

At block 260, method 250 may continue with removing the one or more sacrificial gate structure(s), with removing the sacrificial nanolayers, and with forming a replacement gate structure within the void or recess formed by the absence of a respective sacrificial gate structure. For example, method 250 may include removing the sacrificial gate structure(s) 134 and with removing the sacrificial nanolayers 106 and forming a respective replacement gate structure 170 in place of a respective sacrificial gate structure 134 within the logic region and within the diode region(s) around the active semiconductor nanolayers 108.

At block 262, method 250 may continue with MOL contact formation, with frontside BEOL structure(s) formation, and with bonding a carrier wafer thereto. For example, method 250 may include forming ILD 176.1 upon the replacement gate structure(s) 170 and upon the ILD 176, with forming a respective frontside contact 180 upon one or more S/D regions 164, with forming a respective frontside contact 180 upon doped diode region(s) 166, and with forming a respective frontside contact 180 upon diode doped region(s) 168. Further, method 250 may include forming a through conductive pathway that extends through the entire FEOL and MOL layers. For example, method may include forming the conductive pathway 183, such as a deep via contact 181. Further, method 250 may include forming frontside BEOL network 182 and bonding carrier wafer 184 thereto.

At block 264, method 250 may continue with flipping the wafer assembly and with removing the lower substrate. For example, method 250 may include flipping semiconductor IC device 100 using the carrier wafer 184 and removing lower substrate 101. Further, method 250 may include forming a protective mask in the diode region(s) and removing etch stop layer 103 and the upper substrate 102 in the logic region. Further, the protective mask is removed from the diode region(s) and the etch stop layer 103 is removed within the diode region(s). Upon removal of the etch stop layer 103 in the diode region(s), upper substrate 102 therein may be exposed.

At block 266, method 250 may continue with forming a backside ILD, with patterning the backside ILD to form one or more backside contact openings, with removing one or more of the backside contact placeholder structures, with forming a backside contact within the one or more backside contact trenches, with exposing the through conductive path, with forming a backside resistor, and with forming a backside BEOL network. For example, method 250 may include forming backside ILD 192 within the logic region and within the diode region(s). Still further, method 250 may include forming backside contact opening 194 within the logic region, forming backside contact openings 195 and 196 within the diode region(s). The formation of backside contact opening 194 may exposed one or more of respective backside contact placeholder(s) 162 and may be subsequently removed by a substrative removal technique, such as an etch. Upon removal of the backside contact placeholder(s) 162, the S/D region 164 there above is at least partially exposed. The formation of backside contact opening 195, 196 may exposed one or more of respective backsides of the upper substrate 102 region.

Still further, method 250 may include forming backside contact 204 within backside contact opening 194 in the logic region, may include forming backside contact 205 within backside contact opening 195 in the diode region(s), and may include forming backside contact 206 within backside contact opening 196 in the diode region(s). The backside contact 204 may be formed in contact with or melded against the exposed portion of the S/D region 164 there above. The backside contact 205 may be formed in contact with or melded against the exposed portion of the upper substrate 102 and the backside contact 206 may be formed in in contact with or melded against the exposed portion of the upper substrate 102.

Still further, method 250 may include planarizing the backside of the semiconductor IC device which may result in the exposure of the through conductive path. For example, the backside contacts 204, 205, and 206, the backside ILD 192, and the STI region(s) 130 may be planarized to a depth to expose the bottom surface of the conductive pathway 183.

Still further method 250 may continue with forming a backside resistor 210 upon the exposed bottom surface of the conductive pathway 183. For example, backside resistor 210 is formed upon the revealed backside of the deep via contact 181. Method 200 may further continue with forming backside capping layer 212 upon the backside surfaces of the STI region(s) 130, upon the backside surfaces of one or more backside contacts 204, 205, and/or 206, and upon the backside of and around the backside resistor 210.

Further, method 250 may continue with the forming a backside BEOL network and forming a conductive pathway therein that is connected to the backside resistor. For example, the backside BEOL network 240 is formed upon the backside of semiconductor IC device 100 with a conductive pathway, such as conductive pathway 92, therein that is connected to the backside resistor 210.

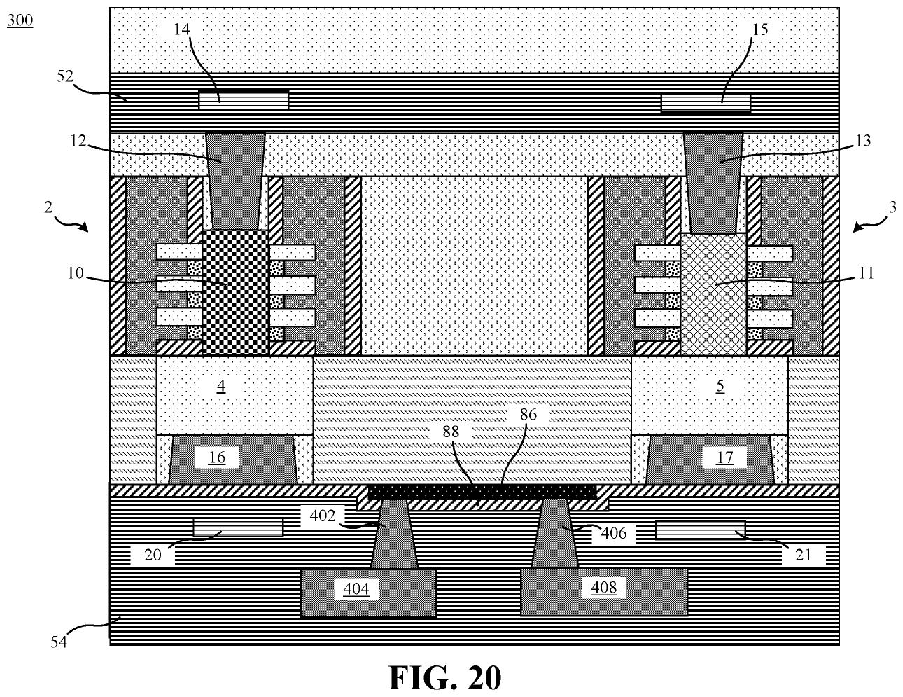

FIG. 20 depicts a semiconductor IC device 300 that includes a backside resistor 86 that is connected to a backside BEOL network 54, in accordance with one or more embodiments of the disclosure. The semiconductor IC device 300 is like semiconductor IC device 50 but does not include the conductive pathway 183. In the present example, the backside resistor 86 in semiconductor IC device 300 is connected to different conductive pathways located within the backside BEOL network 54.

The semiconductor IC device 300 includes a diode 2 and a diode 3. An anode 10 of diode 2 is electrically connected to a conductive pathway 14 within a frontside BEOL network 52 and a cathode 16 of diode 2 is electrically connected to a conductive pathway 20 within the backside BEOL network 54. Similarly, a cathode 11 of diode 3 is electrically connected to a conductive pathway 15 within a frontside BEOL network 52 and an anode 17 of diode 3 is electrically connected to a conductive pathway 21 within the backside BEOL network 54.

Anode 10 may be a P+ doped (i.e., heavily P doped) region and may be directly connected to an intrinsic substrate region 4 and may be connected to a frontside contact 12. Intrinsic substrate region 4 may be directly connected to a backside contact 16. Frontside contact 12 may be electrically connected to the conductive pathway 14 within the front side BEOL network 52. Similarly, backside contact 16 may be electrically connected to the conductive pathway 20 within the backside BEOL network 20. The conductive pathway 14 may carry a positive potential, such as VDD and the conductive pathway 20 may carry a negative or ground potential, such as VSS.

Cathode 11 may be a N+ doped (i.e., heavily N doped) region and may be directly connected to an intrinsic substrate region 5 and may be connected to a frontside contact 13. Intrinsic substrate region 5 may be directly connected to a backside contact 17. Frontside contact 13 may be electrically connected to the conductive pathway 15 within the front side BEOL network 52. Similarly, backside contact 17 may be electrically connected to the conductive pathway 21 within the backside BEOL network 20. The conductive pathway 15 may carry a negative or ground potential, such as VSS and the conductive pathway 21 may carry a positive potential, such as VDD.

In the depicted arrangement, the anode and cathode regions of the diodes 2, 3, may be formed above and below a substrate which allows for a relatively thinner substrate to be utilized and may assist in reducing a thickness of the semiconductor IC device 300.

The semiconductor IC device 300 includes the backside resistor 86. The backside resistor 86 is located vertically between the diodes 2, 3 and the backside BEOL network 54 and is electrically connected to a first conductive pathway 404 within the backside BEOL network 54 and to a second conductive pathway 408 within the backside BEOL network 54. In a particular example, a bottom surface of the backside resistor 86 is electrically connected to the conductive pathways 404, 408.

The backside resistor 86 may route current between the different conductive pathways within the backside BEOL network 54 for microdevice (diode 2, diode 3, GAA FET, or the like) operations. For instance, conductive pathway 404 and conductive pathway 20 may be electrically connected and/or or conductive pathway 408 and conductive pathway 21 may be electrically connected.

For clarity, semiconductor IC device 300 may be fabricated with similar fabrication operations utilized to fabricate semiconductor IC device 100 described above and are not repeated herein. However, the fabrication operations to form the conductive pathway 183 may be omitted and the different conductive pathways in the backside BEOL network 224 may be formed and directly connected with the backside of the backside resistor 210.

Semiconductor IC device 100, 300 or the like, may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The descriptions of the various embodiments of the present disclosure have been presented for purposes of illustration but are not intended to be exhaustive or limited to the embodiments described. Many modifications and variations will be apparent to those of ordinary skill in the art without departing from the scope and spirit of the disclosure. The terminology used herein was chosen to best explain the principles of the embodiment, the practical application or technical improvement over technologies found in the marketplace, or to enable others of ordinary skill in the art to understand the embodiments described herein.

Various embodiments of the present disclosure are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” upon layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

For purposes of the description hereinafter, the terms “upper,” “lower,” “right,” “left,” “vertical,” “horizontal,” “top,” “bottom,” and derivatives thereof relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

What is claimed is:

1. A semiconductor integrated circuit (IC) device comprising:
a frontside back end of line (BEOL) network;
a deep via contact that is directly connected to a backside resistor and that is directly connected to the frontside BEOL network; and
a backside BEOL network comprising a conductive pathway directly connected to the backside resistor.

2. The semiconductor IC device of claim 1, wherein the backside resistor is vertically between the deep via contact and the backside BEOL network.

3. The semiconductor IC device of claim 1, wherein a top surface of the backside resistor is directly connected to a bottom surface of the deep via contact.

4. The semiconductor IC device of claim 1, wherein a bottom surface of the backside resistor is connected to the backside BEOL network.

5. The semiconductor IC device of claim 1, wherein the backside resistor is composed of a first conductive material and the deep via contact is composed of a second conductive material that is different than the first conductive material.

6. The semiconductor IC device of claim 1, wherein the deep via contact and the backside resistor route current between the frontside BEOL network and the backside BEOL network.

7. The semiconductor IC device of claim 1, wherein the deep via contact and the backside resistor provide a substantially same electrical potential to both the frontside BEOL network and to the backside BEOL network.

8. The semiconductor IC device of claim 1, wherein a top surface of the backside resistor is coplanar with a bottom surface of a backside contact associated with a front end of line (FEOL) microdevice.

9. The semiconductor IC device of claim 1, wherein a bottom surface of the backside resistor is below a bottom surface of a backside contact associated with a front end of line (FEOL) microdevice.

10. The semiconductor IC device of claim 1, wherein the backside resistor is below a shallow trench isolation (STI) region.

11. The semiconductor IC device of claim 1, wherein the backside resistor is horizontally between a first front end of line (FEOL) diode and a second FEOL diode.

12. A semiconductor integrated circuit (IC) device comprising:
a backside resistor; and
a backside back end of line (BEOL) network comprising a first conductive pathway directly connected to the backside resistor and a second conductive pathway directly connected to the backside resistor.

13. The semiconductor IC device of claim 12, wherein the backside resistor is vertically between a front end of line (FEOL) shallow trench isolation (STI) region and the backside BEOL network.

14. The semiconductor IC device of claim 12, wherein a bottom surface of the backside resistor is directly connected to the first conductive pathway.

15. The semiconductor IC device of claim 12, wherein a bottom surface of the backside resistor is directly connected to the second conductive pathway.

16. The semiconductor IC device of claim 12, wherein the backside resistor is composed of a first conductive material and both the first conductive pathway and the second conductive pathway are composed of a second conductive material that is different than the first conductive material.

17. The semiconductor IC device of claim 12, wherein the backside resistor routes current between the first conductive pathway and the second conductive pathway within the backside BEOL network.

18. The semiconductor IC device of claim 12, wherein a top surface of the backside resistor is coplanar with a bottom surface of a backside contact associated with a front end of line (FEOL) microdevice.

19. The semiconductor IC device of claim 12, wherein the backside resistor is horizontally between a first front end of line (FEOL) diode and a second FEOL diode.

20. A semiconductor integrated circuit (IC) device method comprising:
forming a backside resistor upon a backside of a front end of line (FEOL) shallow trench isolation (STI) region and upon a bottom surface of a deep via contact;
forming a backside capping layer upon and around the backside resistor and upon the FEOL STI region; and
forming a backside back end of line (BEOL) network upon the backside capping layer, the backside BEOL network comprising a conductive pathway directly connected to the backside resistor.
